(19) United States
(12) Patent Application Publication
(10) Pub. No.: US 2008/0061340 A1
(43) Pub. Date: Mar. 13, 2008

(54) MEMORY CELL ARRAY AND METHOD OF FORMING THE MEMORY CELL ARRAY

(75) Inventors: Lars Heineck, Dresden (DE); Martin Popp, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/470,792

(22) Filed: Sep. 7, 2006

(51) Int. Cl. H01L 29/94

(52) U.S. Cl. 257/301

(57) ABSTRACT

A memory cell array having a plurality of memory cells is disclosed. In one embodiment, each memory cell includes a storage capacitor and an access transistor, a plurality of bit lines orientated in a first direction, a plurality of word lines orientated in a second direction, the second direction being perpendicular to the first direction, a semiconductor substrate with a surface, a plurality of active areas being formed in the semiconductor substrate, each active area extending in the second direction, the access transistors being partially formed in the active areas and electrically coupling corresponding ones of the storage capacitors to corresponding bit lines, wherein a gate electrode of each of the access transistors is connected with a corresponding word line, a capacitor dielectric of the storage capacitor has a relative dielectric constant of more than 8, and the word lines are disposed above the bit lines.

### FIELD OF THE INVENTION

The invention relates to memory cell arrays with a plurality of memory cells, such as dynamic random access memory (DRAM) cells.

### BACKGROUND

Memory cells of a dynamic random access memory (DRAM) generally comprise a storage capacitor for storing an electrical charge that represents information to be stored, and an access transistor connected with the storage capacitor. The access transistor includes first and second source/drain regions, a channel connecting the first and second source/drain regions, and a gate electrode controlling an electrical current flowing between the first and second source/drain regions. The gate electrode is electrically insulated from the channel by a gate dielectric. The transistor is usually partially formed in a semiconductor substrate, such as a silicon substrate. The portion in which the transistor is formed, generally is denoted as the active area.

In conventional DRAM memory cell arrays, the gate electrode forms part of a wordline. By addressing the access transistor via the corresponding wordline, the information stored in the storage capacitor is read out.

In currently-used DRAM memory cells, the storage capacitor is implemented as a trench capacitor in which the two capacitor electrodes are disposed in a trench that extends into the substrate in a direction perpendicular to the substrate surface. According to another implementation of a DRAM memory cell, the electrical charge is stored in a stacked capacitor formed above the surface of the substrate.

Generally, a DRAM memory cell array is needed, in which the area of the memory cells is reduced. Moreover, the capacitance of the storage capacitor should exceed a minimum value.

For these and other reasons, there is a need for the present invention.

### SUMMARY

The present invention provides a memory cell array and method of forming a memory cell array. In one embodiment, according to the present invention, a memory cell array includes a plurality of memory cells, each memory cell including a storage capacitor and an access transistor, a plurality of bit lines orientated in a first direction, a plurality of word lines orientated in a second direction, the second direction being perpendicular to the first direction, a semiconductor substrate with a surface, a plurality of active areas being formed in the semiconductor substrate, each active area extending in the second direction, the access transistors being partially formed in the active areas and electrically coupling corresponding ones of the storage capacitors to corresponding bit lines, wherein a gate electrode of each of the access transistors is connected with a corresponding word line, a capacitor dielectric of the storage capacitor has a relative dielectric constant of more than 8, and the word lines are disposed above the bit lines.

In another embodiment, a memory cell array includes a plurality of memory cells, each memory cell including a storage capacitor and an access transistor, a plurality of bit lines orientated in a first direction, a plurality of word lines orientated in a second direction, the second direction being perpendicular to the first direction, a semiconductor substrate with a surface, a plurality of active areas being formed in the semiconductor substrate, each active area extending in the second direction, the access transistors being partially formed in the active areas and electrically coupling corresponding ones of the storage capacitors to corresponding bit lines, each transistor having a first source/drain region connected with an electrode of the storage capacitor, a second source/drain region adjacent to the substrate surface, a channel connecting the first and the second source/drain regions, the channel region being disposed in the active area, and a gate electrode disposed along the channel region, the gate electrode controlling an electric current flowing between the first and the second source/drain regions, the gate electrode being connected with one of the word lines, wherein each of the gate electrodes includes a bottom side, each word line includes a bottom side, a bottom side of the gate electrodes being disposed beneath the bottom side of the word lines, and the word lines being disposed above the bit lines, wherein each of the storage capacitor includes a first and a second capacitor electrode, and a dielectric layer disposed between the first and the second capacitor electrodes, the capacitor dielectric having a relative dielectric constant of more than 8.

In another embodiment, the present invention provides a memory cell array including a plurality of memory cells, each memory cell including a storage capacitor and an access transistor, a plurality of bit lines orientated in a first direction, a plurality of word lines orientated in a second direction, the second direction being perpendicular to the first direction, a semiconductor substrate with a surface, a plurality of active areas being formed in the semiconductor substrate, each active area extending in the second direction, the access transistors being partially formed in the active areas and electrically coupling corresponding ones of the storage capacitors to corresponding bit lines, wherein an electrode of the capacitor is connected with the access transistor via a conductive structure which is disposed above the semiconductor substrate, wherein the gate electrode of each of the access transistors is connected with a corresponding word line, and wherein the word lines are disposed above the bit lines.

In another embodiment, the present invention provides a memory cell array including a plurality of memory cells, each memory cell including a storage capacitor and an access transistor, a plurality of bit lines orientated in a first direction, a plurality of word lines orientated in a second direction, the second direction being perpendicular to the first direction, a semiconductor substrate with a surface, a plurality of active areas being formed in the semiconductor substrate, each active area extending in the second direction, the access transistors being partially formed in the active areas and electrically coupling corresponding ones of the storage capacitors to corresponding bit lines, wherein the gate electrode of each of the transistors is disposed in a groove extending in the semiconductor substrate, the gate electrode includes plate-like portions so that the gate electrode encloses a channel of the transistor at three sides thereof, the gate electrode of each of the access transistors is connected with a corresponding word line, and wherein the word lines are disposed above the bit lines.

In another embodiment, the present invention provides a method of forming a memory cell array, including providing a semiconductor substrate having a surface, providing storage capacitors, defining active areas in the semiconductor substrate, providing access transistors in corresponding ones of the active areas, providing a plurality of bit lines extending along a first direction, and providing a plurality of word lines extending along a second direction, each word line being connected with a plurality of gate electrodes, wherein the active areas extend in the second direction, wherein providing bit lines occurs before providing word lines, and wherein providing a capacitor dielectric of the storage capacitor occurs after providing the bitlines.

In another embodiment, the present invention provides a method of forming a memory cell array, including providing a semiconductor substrate having a surface, providing storage capacitors by forming trenches in the semiconductor substrate, the trenches having sidewalls, and filling the trenches with suitable materials so that part of the materials protrude from the substrate surface thereby forming protruding portions, defining active areas in the semiconductor substrate, providing access transistors in corresponding ones of the active areas, by providing a first and a second source/drain regions, a channel connecting the first and second source/drain regions and a gate electrode that is disposed along the channel, providing a plurality of bit lines extending along a first direction, each of the bit lines being in contact with a corresponding second source/drain region, and providing a plurality of word lines extending along a second direction, each word line being connected with a plurality of gate electrodes, wherein the active areas extend in the second direction, providing bit lines occurs before providing word lines, and an additional ion implantation is performed so as to implant ions into the second source/drain region, this additional ion implantation being an angled ion implantation taking the protruding portions as a shadowing mask.

In another embodiment, the present invention provides a method of forming a memory cell array, including providing a semiconductor substrate having a surface, providing storage capacitors, defining active areas in the semiconductor substrate, providing access transistors in corresponding ones of the active areas by providing corresponding gate electrodes disposed along a channel of the transistors, respectively, providing a plurality of bit lines extending along a first direction, and providing a plurality of word lines extending along a second direction, each word line being connected with a plurality of gate electrodes, wherein the active areas extend in the second direction, wherein providing bit lines occurs before providing word lines, and wherein providing the gate electrodes occurs after providing the bit lines.

In another embodiment, the present invention provides a memory cell array, including a plurality of memory cells, each memory cell having a means for storing an electrical charge and an access transistor, a plurality of bit lines orientated in a first direction, a plurality of word lines orientated in a second direction, the second direction being perpendicular to the first direction, the access transistors coupling corresponding ones of the means for storing an electrical charge to corresponding bit lines, wherein each of the access transistors includes means for controlling an electrical current flow, the means being connected with a corresponding word line, a capacitor dielectric of the means for storing an electrical charge has a relative dielectric constant of more than 8, and the word lines are disposed above the bit lines.

In any of the embodiments listed above, the succession in which the individual process is listed does not necessarily define the succession in which the process is actually performed. In addition, each of the processes may comprise various sub-processes so that the succession of the sub-processes of one process may be mixed with the succession of the sub-processes of another process. To put it more precisely, if a method recites “providing storage capacitors” and “providing access transistors”, part of the components of the storage capacitor may be provided before or after providing a first part of the components of the access transistor, a second part of the components of the access transistor being provided before or after providing a second part of the components of the storage capacitor.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A illustrates a cross-sectional view of the upper portion of the completed memory cell array;

FIG. 1B illustrates a cross-sectional view of the trench capacitors forming part of the memory cell array;

FIG. 1C illustrates a plan view of the completed memory cell array;

FIG. 2 illustrates a cross-sectional view of a substrate including a trench;

FIG. 3 illustrates a cross-sectional view of the substrate after performing a first processing step;

FIG. 4 illustrates a cross-sectional view of the substrate after depositing a layer in the upper portion of the trench;

FIG. 5 illustrates a cross-sectional view of the substrate after widening the trench in the bottom portion thereof;

FIG. 6 illustrates a cross-sectional view of the substrate after depositing the first capacitor electrode;

FIG. 7 illustrates a cross-sectional view of the substrate after recessing the first capacitor electrode;

FIG. 8 illustrates a cross-sectional view of the substrate after depositing a silicon dioxide layer;

FIG. 9 illustrates a cross-sectional view of the substrate after providing a sacrificial filling;

FIG. 10A illustrates a cross-sectional view of the substrate including the upper portion of several trenches;

FIG. 10B illustrates a plan view of the substrate including a plurality of trenches;

FIG. 11 illustrates a cross-sectional view of the substrate after recessing the materials in the upper portion of a trench;

FIG. 12 illustrates a cross-sectional view of the substrate after depositing an amorphous silicon layer;

FIG. 13 illustrates a cross-sectional view of the substrate when performing a tilted ion implantation step;

FIG. 14 illustrates a cross-sectional view of the substrate after performing an etching step;

FIG. 15 illustrates a cross-sectional view of the substrate after performing a further etching step;

FIG. 16 illustrates a cross-sectional view of the substrate after depositing a further silicon dioxide layer;

FIG. 17A illustrates a cross-sectional view of the substrate after providing a conductive strap material;

FIG. 17B illustrates a plan view of the substrate after depositing the conductive strap material;

FIG. 18A illustrates a cross-sectional view of the substrate after forming a further silicon dioxide layer;

FIG. 18B illustrates a plan view of the substrate after defining the isolation trenches;

FIG. 19 illustrates a cross-sectional view of the substrate after depositing a further silicon dioxide layer;

FIG. 20 illustrates a cross-sectional view of the substrate after removing the pad nitride layer;

FIG. 21 illustrates a cross-sectional view of the substrate when performing a tilted ion implantation step;

FIG. 22 illustrates a cross-sectional view of the substrate after providing a further silicon nitride layer;

FIG. 23 illustrates a cross-sectional view of the substrate when performing a tilted ion implantation step;

FIG. 24 illustrates a cross-sectional view of the substrate after removing the undoped portions;

FIG. 25A illustrates a cross-sectional view of the substrate after performing an oxidation step;

FIG. 25B illustrates a plan view of the substrate after performing the oxidation step;

FIG. 26 illustrates a cross-sectional view of the substrate after providing a further silicon layer;

FIG. 27 illustrates a cross-sectional view of the substrate after providing a further silicon layer;

FIG. 28 illustrates a cross-sectional view of the substrate after removing the further silicon layer;

FIG. 29 illustrates a cross-sectional view of the substrate after providing a layer stack constituting the bitlines;

FIG. 30 illustrates a cross-sectional view of the substrate in the peripheral portion;

FIG. 31A illustrates a cross-sectional view of the substrate after patterning the bitlines;

FIG. 31B illustrates a plan view of the substrate after patterning the bitline;

FIG. 32A illustrates a cross-sectional view of the peripheral portion after patterning the gate electrodes;

FIG. 32B illustrates a cross-sectional view of the array portion after providing a silicon nitride liner;

FIG. 33 illustrates a cross-sectional view of the substrate after providing a further silicon layer;

FIG. 34 illustrates a cross-sectional view of the substrate after providing a hard mask layer;

FIG. 35 illustrates a cross-sectional view of the substrate after selectively removing silicon material;

FIG. 36 illustrates a cross-sectional view after defining gate grooves;

FIG. 37 illustrates a cross-sectional view of the substrate after providing a gate insulating layer;

FIG. 38 illustrates a cross-sectional view of the substrate after providing a silicon dioxide spacer;

FIG. 39A illustrates a cross-sectional view of the substrate after defining pocket structures;

FIG. 39B illustrates a cross-sectional view of the structure illustrated in FIG. 39A in another direction;

FIG. 40 illustrates a cross-sectional view of the substrate after depositing a further silicon dioxide layer;

FIG. 41A illustrates a cross-sectional view of the substrate after depositing a gate electrode material;

FIG. 41B illustrates a cross-sectional view of the structure illustrated in FIG. 41A taken along a different direction;

FIG. 42 illustrates a cross-sectional view of the substrate after depositing a further silicon nitride layer;

FIG. 43 illustrates a cross-sectional view of the substrate after removing silicon material;

FIG. 44 illustrates a cross-sectional view of the substrate after opening the upper portion of the trenches;

FIG. 45 illustrates a cross-sectional view of the substrate after removing the sacrificial filling of the trenches;

FIG. 46 illustrates a cross-sectional view of the substrate after depositing a dielectric material and a resist material;

FIG. 47 illustrates a cross-sectional view of the substrate after recessing the resist material;

FIG. 48 illustrates a cross-sectional view of the substrate after providing the capacitor dielectric and the second capacitor electrode;

FIG. 49A illustrates a cross-sectional view of the substrate after providing a further insulating material;

FIG. 49B illustrates a plan view of the substrate after depositing a further insulating material; and

FIG. 50 illustrates a schematic layout of the memory device having the memory cell of the present invention.

### DETAILED DESCRIPTION

In the following detailed description, reference is made to the accompanying drawings, which form a part hereof and in which are illustrated by view of illustration specific embodiments in which the invention may be practiced. In this regard, directional terminology such as “Top”, “Bottom”, “Front”, “Back”, “Leading”, “Trailing”, etc. is used with reference to the orientation of the figures being described. Because components of embodiments of the present invention can be positioned in a number of different orientations, the directional terminology is used for purposes of illustration and in now way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

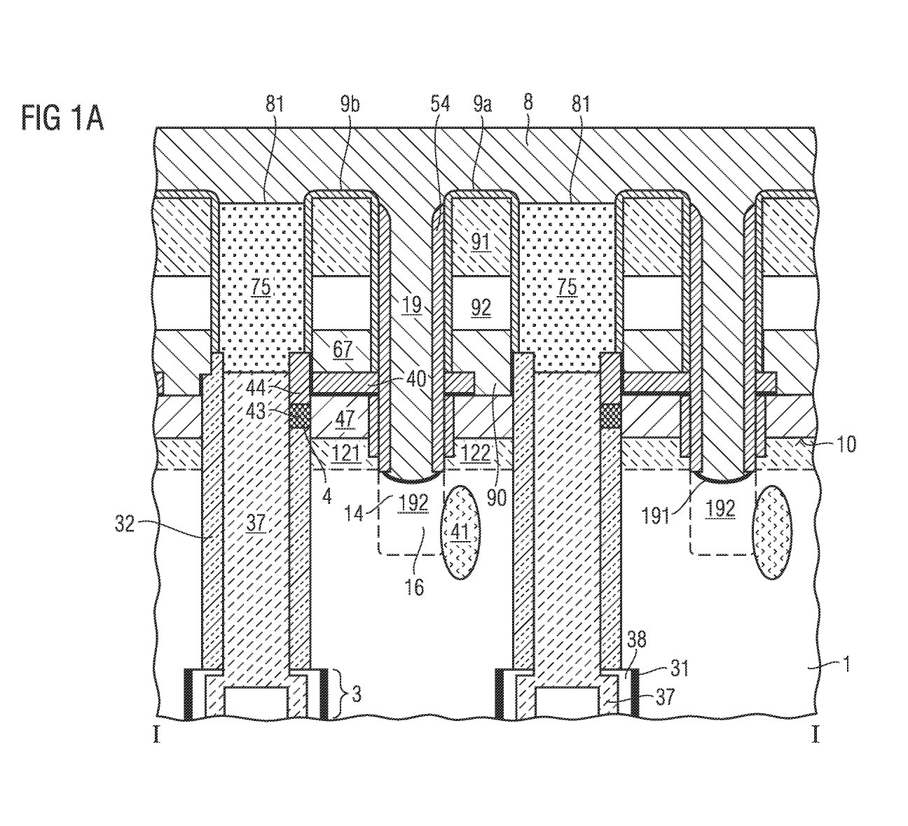

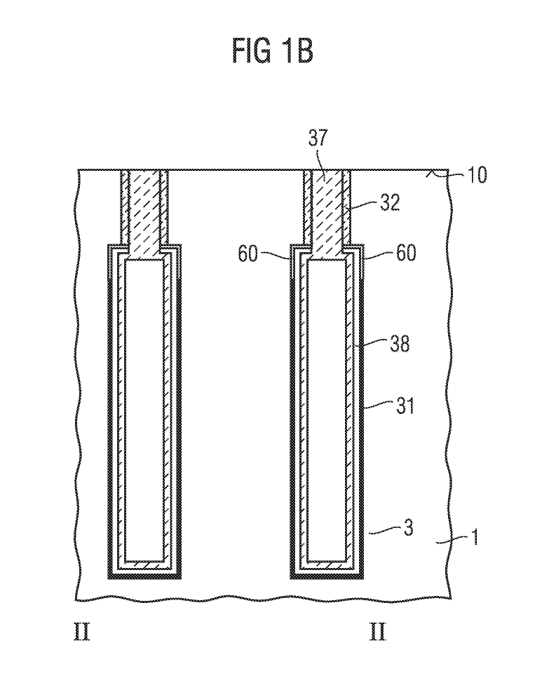

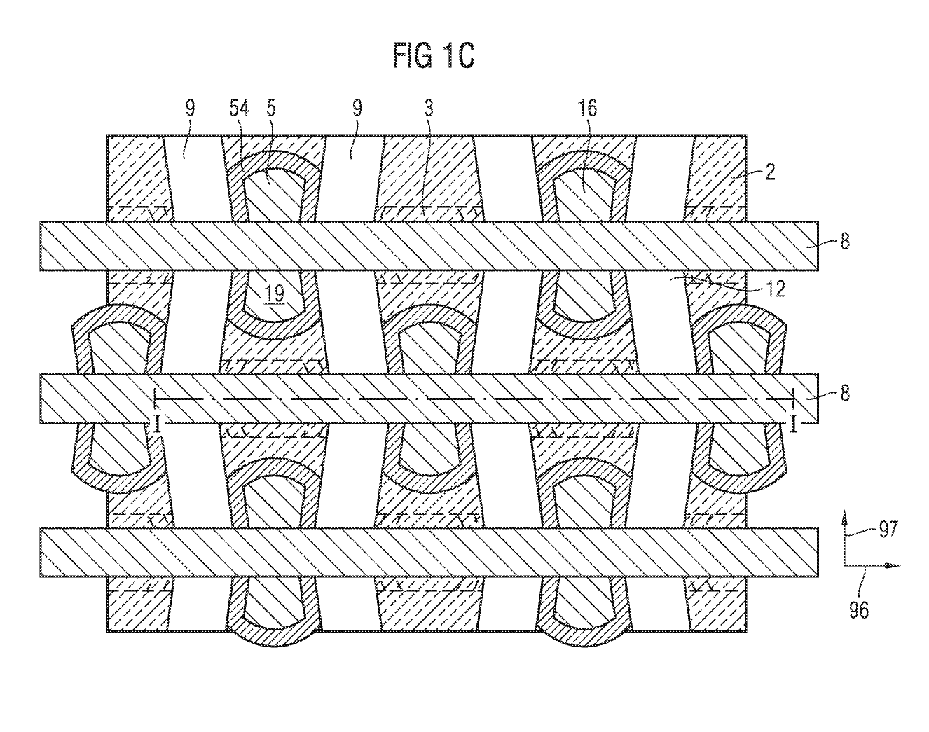

FIG. 1A illustrates a cross-sectional view of the upper portion of a memory cell array of the present invention. Each memory cell includes a storage capacitor implemented as a trench capacitor 3. A complete illustration of the trench capacitor is for example illustrated in FIG. 1B. The trench capacitor 3 is formed in a trench extending in the semiconductor substrate 1. For example, the semiconductor substrate may be a silicon substrate 1 and the trench capacitor extends perpendicularly into the substrate surface. The trench capacitor includes a first capacitor electrode 31, which is formed adjacent to the sidewalls of the trench, a gate dielectric 38 which is formed on the surface of the first capacitor electrode 31 as well as a second capacitor electrode 37 which is formed on a surface of the dielectric layer 38. In particular, in the upper portion of the trench, the second capacitor electrode 37 entirely fills the trench opening. In the upper portion of the trench, in addition, an isolation collar 32 is formed so as to avoid a parasitic vertical transistor which otherwise could be formed in the upper portion of the trench.

A second capacitor electrode 37 is connected with a conductive strap material 43 which is disposed along one side of the trench capacitor. The conductive strap material is disposed above the isolation collar 32 on one side of the trench. The conductive strap material 43 electrically connects the second capacitor electrode 37 with a conductive material 47 which is disposed on the semiconductor substrate surface 10. A first source/drain region 121 is disposed beneath this conductive material 47. Differently stated, the strap connecting the second capacitor electrode 37 with the first source/drain region 121 is completely disposed above the substrate surface 10.

A transistor 16 is formed by the first and second source/drain regions 121, 122. For example, the first and second source/drain regions 121, 122 may be doped with a dopant of the first conductivity type. In particular, a channel is formed between the first and the second source/drain regions 121, 122. The conductivity of the channel 14 is controlled by the gate electrode 19. For example, the gate electrode 19 may be formed in such a manner that a so-called EUD (“Extended U-Groove Device”) is formed. In such an EUD a gate electrode 19 is disposed in a gate groove which is formed in the substrate surface. Moreover, as is indicated by broken lines in FIG. 1A, in a plane before and behind the illustrated plane of the drawing, plate-like portions 192 of a gate electrode are formed, so that the channel 14 is laterally enclosed by the plate-like portions 192. For example, the second source/drain portion, which is connected with a corresponding bitline, may be heavily doped so that the contact resistance is reduced. Optionally, a doped portion 41, which is doped with a dopant of the second conductivity type, may be provided. The second source/drain portion 122 is connected with a corresponding bitline 9A. In particular, as can be seen from FIG. 1A, a bitline contact 90 is formed by opening a corresponding insulating layer 40, so that, as a result, the bitline 9A is directly in contact with a silicon layer 47.

As can further be seen from FIG. 1A, the gate electrode 19 is connected with a corresponding wordline 8. The wordline 8 extends in a direction which is parallel to the plane of the drawing and parallel to the direction of the active area 12. In particular, the direction of the active area 12 is parallel to the direction connecting the first and the second source/drain regions 121, 122. Moreover, as can be seen from FIG. 1A, the bitlines 9 are disposed beneath the wordline 8. To be more specific, the bitlines 9 are formed so as to be very close to the substrate surface 10, whereas the wordlines 8 are disposed above the bitlines 9. The bitlines 9 which are directly in contact with a second source/drain region 122 are referred to as an active bitline 9a, whereas the wordlines which are insulated from the first source/drain region 121 are referred to as a passing bitline 9b. A second capacitor electrode 37 is insulated from the wordline 8 by an insulating material 75. Moreover, as can be taken from FIG. 1A, the bitlines 9 are arranged in such a manner, that they are not disposed directly above the trench capacitor 3. In other words, an upper surface of the second capacitor electrode 37 is not covered by any of the bitlines 9a, 9b. As a result, as will be explained later, the inner portion of each of the trench capacitors 3 can be accessed without removing or destroying part of the bitlines 9.

FIG. 1B illustrates a cross-sectional view of the substrate illustrating trench capacitors 3 being formed in the substrate 1. For example, the trench may extend to a depth of 3 to 8 μm below the substrate surface 10. For example, the trench may have a diameter in the upper portion of approximately 27 to 80 nm, whereas the diameter in the lower portion thereof is approximately 37 to 150 nm. In a cross-sectional view which is perpendicular to the illustrated cross-sectional view, the diameters may be different, for example, they may be larger. A first capacitor electrode 31 is formed adjacent to the sidewall of the trench. For example, the first capacitor electrode 31 may be implemented as a heavily p-doped portion. Alternatively, the first capacitor electrode may be formed of a conductive material such as a metal layer or others. In addition, the first capacitor electrode 31 may be implemented as a carbon electrode. In particular, in this respect “carbon” refers to a layer which is made of elemental carbon, i.e. carbon which is not contained in a chemical compound. For example, an additive such as hydrogen may be added to such a carbon layer. Such a carbon layer may be deposited by a CVD-method.

Adjacent to the first capacitor electrode 31, a capacitor dielectric 38 is formed. For example, any generally known dielectric may be used as the dielectric layer. Moreover, a so-called high-k dielectric may be used in order to increase the capacitance of the capacitor formed. For example, the term “high-k dielectric” refers to a dielectric having a relative dielectric constant εᵣ/ε₀ of more than 8, for example, more than 20 and, as a further example, more than 30. Examples of the dielectric material comprise silicon dioxide, silicon nitride, barium strontium titanate (BST), strontium titanate (SrTiO₃), zirconium oxide (ZrO₂), hafnium oxide (HfO), aluminium oxide (Al₂O₃), HfSiON and layer stacks having any of these layers. Moreover, a second capacitor electrode 37 is formed on the surface of the capacitor dielectric 38. For example, materials suitable for use as the second capacitor electrode 37 comprise polysilicon, conductive materials such as metal, for example titanium nitride, or conductive carbon (graphite). The thickness of the dielectric layer 38 may be approximately 3 to 12 nm, for example, 4 to 10 nm. In the upper portion of the trench capacitor 3 an isolation collar 32 is provided as is conventional.

FIG. 1C illustrates a plan view of the memory cell array illustrated in FIG. 1A. As can be seen, a plurality of wordlines 8 are arranged parallel to each other. The wordlines 8 are connected with corresponding gate electrodes 19 forming part of a corresponding transistor. The gate electrodes 19 are arranged in a checkerboard pattern. In particular, in such a checkerboard pattern, the gate electrodes 19 of adjacent rows are staggered, so that the gate electrodes 19 of the first row are disposed at a position corresponding to a space of the gate electrodes 19 of a second row and vice versa. Between adjacent gate electrodes 19, trench capacitors 3 are disposed. A plurality of wordlines 8 are disposed so as to extend in a first direction, whereas a plurality of bitlines 9 are disposed so as to extend in a second direction.

As is illustrated, the wordlines 8 are formed as straight lines. By way of example, the bitlines may be formed so as to comprise straight segments of lines, the bitlines wiggling around the gate electrodes. Accordingly, a line connecting the outer most position of a certain bitline with another outer most position of the bitline on the other side thereof can be connected with a straight line. This straight line extends along the second direction. In this illustrated plan view, the gate electrodes 19 have a kidney-like shape so as to better exploit the area needed.

Although in the embodiment illustrated in FIG. 1A the storage capacitor is implemented as a trench capacitor, the storage capacitor may be implemented in an arbitrary manner. For example, at least part of the capacitor may extend above the substrate surface. For example, the first and the second capacitor electrodes 31, 37 as well as the capacitor dielectric 38 may be disposed above the substrate surface 10.

In the following, the method for forming the memory cell illustrated in FIGS. 1A to 1C will be described in more detail.

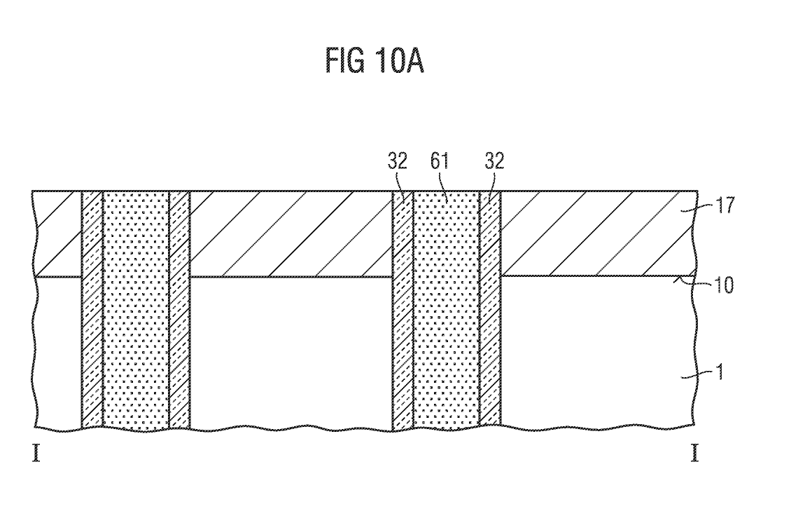

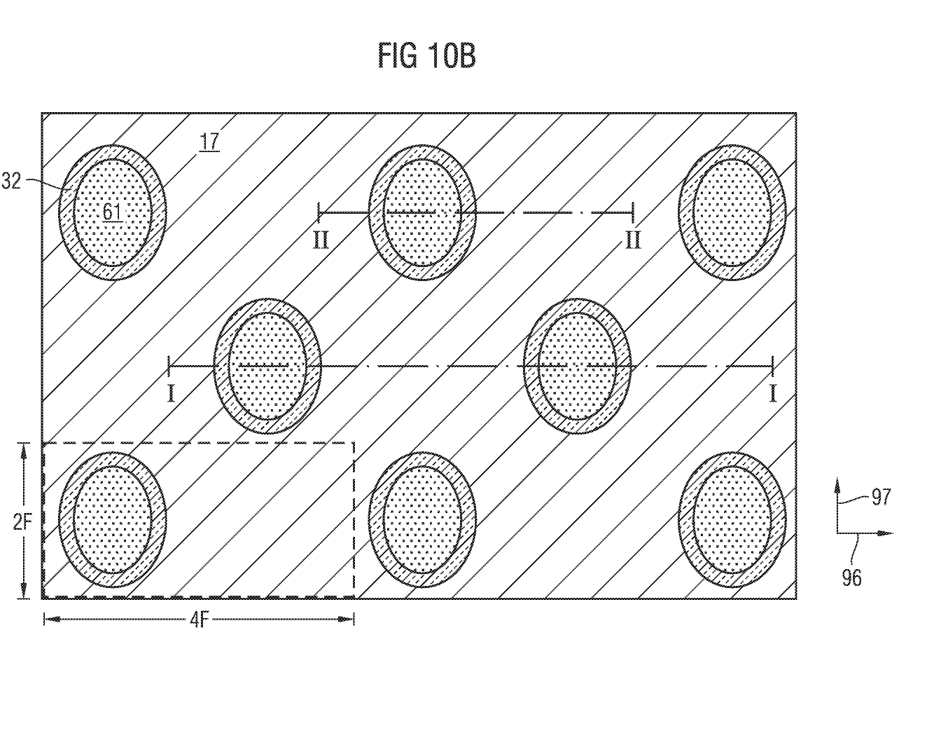

In the following Figures, cross-sectional views between II and II will be illustrated. For example, the position of these cross-sectional views can be taken from FIG. 10B.

In the following description various selective etching processes are performed. In the context of the present specification, the term “selective etching step” means, that a first material is etched selectively with respect to a second material and optionally, to a third material. In particular, this means, that the second and third materials are etched at a much lower etching rate than the first material. For example the ratio of the etching rates may be approximately 1:3 to 1:10.

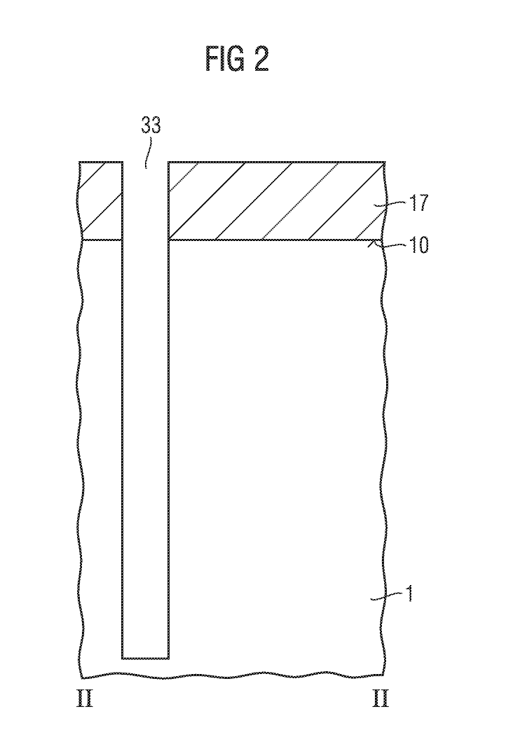

Starting point for implementing the method of the present invention is a semiconductor substrate, for example, a p-doped silicon substrate 1. A silicon nitride layer 17 (pad nitride layer) having a thickness of approximately 100 to 150 nm is deposited on the surface 10 of the semiconductor substrate. In addition, a trench 33 is etched into the substrate surface 10 as is conventional. For example, a hard mask layer be deposited on the surface of the silicon nitride layer 17. The hard mask layer is patterned using a photolithographic mask so as to define the openings in which the trenches are to be etched. Thereafter, using the patterned hard mask layer as an etching mask, the trenches are etched in a manner as is conventional. Thereafter, the remaining portions of the hard mask layer are stripped from the surface. For example, in the illustrated cross-section, the trench 33 may have a width of 20 to 81 nm and a depth of 3 to 8 μm, measured from the substrate surface 10. The resulting structure is illustrated in FIG. 2.

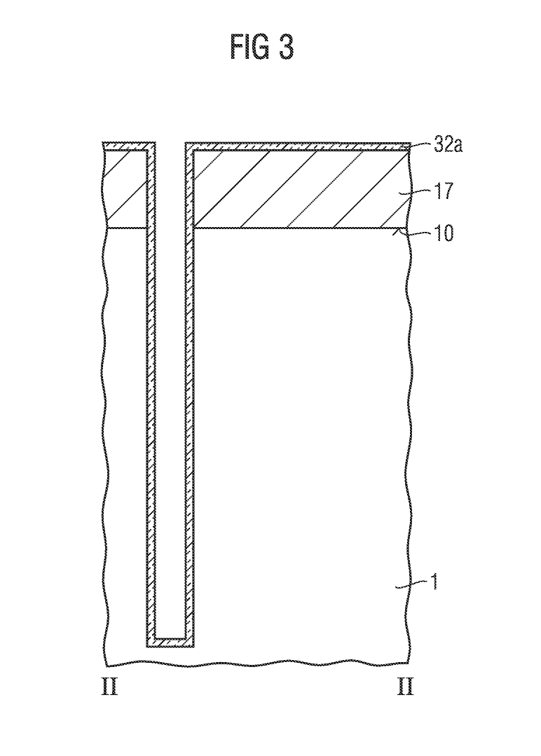

In the next process, a silicon dioxide layer 32a having a thickness of approximately 10 to 17 nm is formed on the resulting surface. For example, the silicon dioxide layer 32a may be formed by a thermal oxidation process, followed by a process of depositing a silicon dioxide layer. The resulting structure is illustrated in FIG. 3.

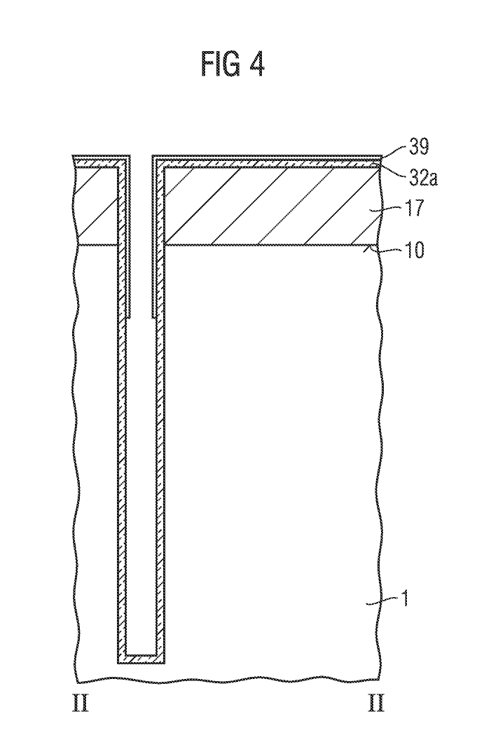

Thereafter a cover layer 39 is deposited in the upper portion of the trench 3. For example, the cover layer 39 may be made of Al₂O₃. For example, the cover layer 39 may be provided by conformally depositing a layer and etching the layer back in the lower portion thereof as is conventional. Moreover, a special deposition method can be employed, by which the material of the cover layer 39 is only deposited in the upper trench portion. The resulting structure is illustrated in FIG. 4. As can be seen, the upper portion of the silicon dioxide layer 32a is covered with the cover layer 39.

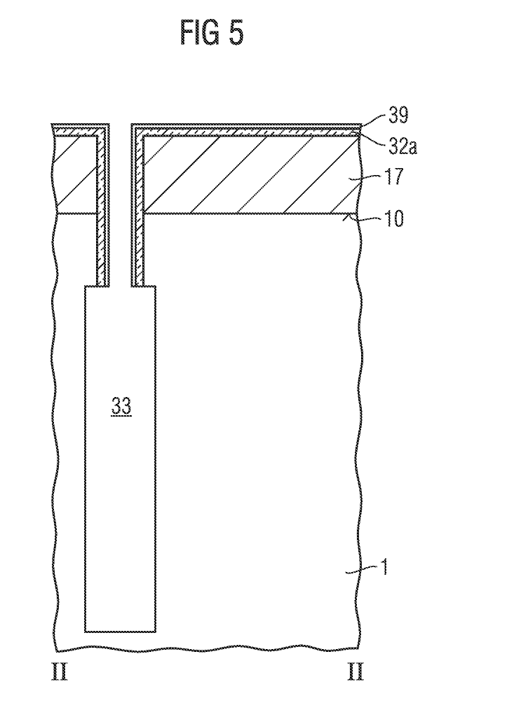

In the next process, taking the cover layer 39 as an etching mask, the exposed portions of the silicon dioxide layer 32a are etched. After etching the silicon dioxide layer 32a in the lower trench portion, an etching process of etching substrate material 1 may be performed so as to enlarge the diameter of the trench 33 in the lower portion thereof. For example, this may be accomplished by dry or wet etching, for example, with NH₄OH. The resulting structure is illustrated in FIG. 5. As can be seen, in the upper portion of the trench 33, a silicon dioxide layer 32a is provided, the silicon dioxide layer 32a being covered with a cover layer 39. Moreover, in the lower trench portion, the diameter of the trench is enlarged with respect to the upper portion thereof. For example, the diameter may be enlarged by 10 to 60 nm. Then, the surface of the trench is heavily doped, for example, with an n-dopant so as to form the buried plate and reduce the contact resistance. This may, for example, be accomplished by gas phase doping.

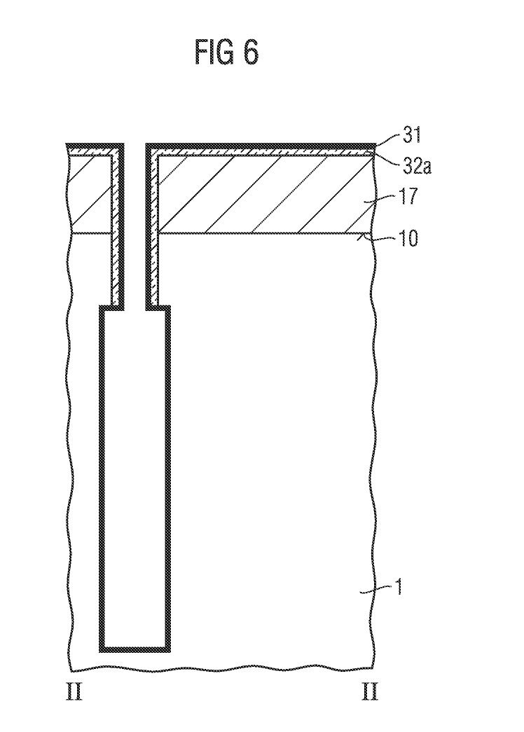

Thereafter, the cover layer 39 is removed by a generally known etching method. Then, optionally the first capacitor electrode 31 is defined. For example, a chemical vapor deposition method can be employed so as to deposit a carbon layer having a thickness of approximately 5 nm. Nevertheless as is obvious to the person skilled in the art any other material may be deposited for constituting the first capacitor electrode 31. In addition, the first capacitor electrode may as well be implemented as a heavily n-doped portion. The resulting structure is illustrated in FIG. 6. As can be seen, a carbon layer 31 is deposited on the entire surface. As is clearly to be understood, the first capacitor electrode may as well be provided after providing the gate electrodes and bitlines. In this case after defining the isolation collar 32 instead of forming the first capacitor electrode, a sacrificial filling may be provided.

In the next process, a recess etching process is performed. As a result, the carbon electrode is present only on the lower sidewall portion of the trench. To be more specific, the carbon layer 31 is removed from the surface of the silicon dioxide layer 32a. As an alternative, the carbon electrode may be formed by a selective carbon deposition method, by which carbon is deposited selectively on silicon material. During this method no carbon is deposited on the silicon dioxide layer 32a. Thereafter, a further carbon recessing process is performed so as to provide the exposed sidewall portion 34. For example, this etching process may be performed with an O₂ containing chemistry.

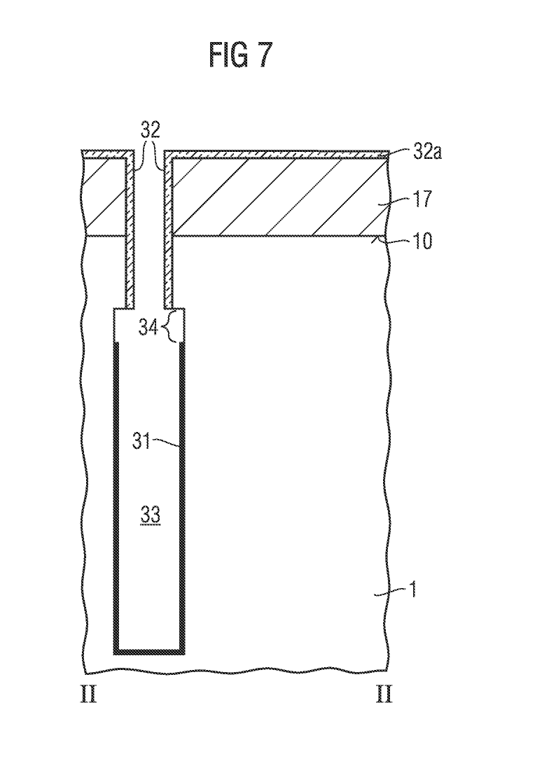

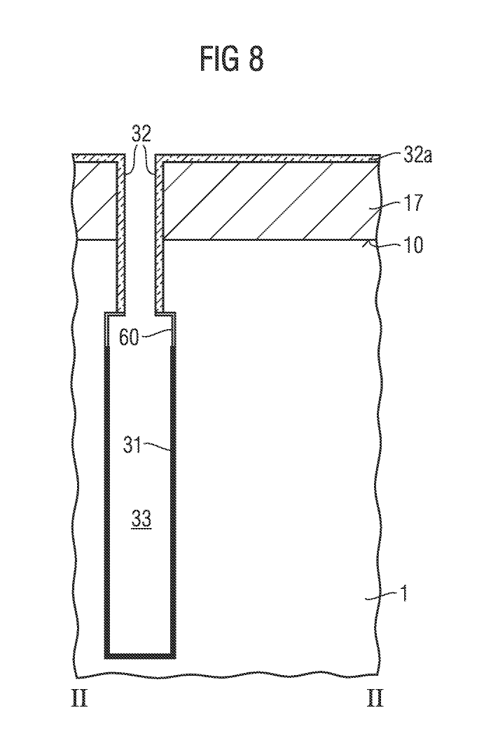

The resulting structure is illustrated in FIG. 7. As can be seen, the first capacitor electrode 31 is formed in the lower portion of the trench 33, leaving an uncovered sidewall portion 34. In the next process, a protective layer 60 is provided on the surface of the exposed sidewall portion 34. For example this protective layer 60 may be formed by an oxidation process or by a nitridation process so as to form SiO₂ or Si₃N₄ respectively. The resulting structure is illustrated in FIG. 8. As can be seen, above the first capacitor electrode 31, on each of the sidewalls the protective layer 60 is formed.

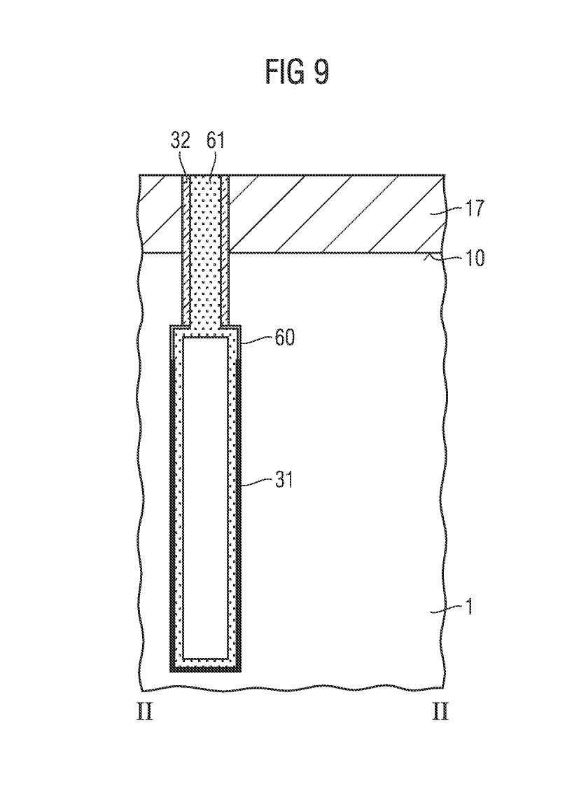

In the next process, a sacrificial filling 61 is provided so as to completely fill the upper portion of the trench 33. For example, a undoped polysilicon layer may be deposited, for example by a LPCVD (liquid phase chemical vapor deposition) method at a temperature of approximately 550° C. Thereafter, a CMP (chemical mechanical polishing) method is performed so as to obtain a planarized surface. As can be seen from FIG. 9, a sacrificial filling 61 is provided, thereby generating a void inside the lower trench portion. Thereby, it becomes easier to remove the sacrificial filling 61 from the trench in a later processing step.

FIG. 10A illustrates a cross-sectional view of the upper portion of the substrate surface 1. As can be seen on the substrate surface 10, a silicon nitride layer 17 is formed. Trenches 33 are formed in the substrate surface 10. An isolation collar 32 is formed in the upper portion of the trench, and a sacrificial filling 61 is provided, so that the surface of the trenches is completely closed.

FIG. 10B illustrates a plan view of the substrate illustrated in FIG. 10A. As can be seen, a plurality of trenches 33 are formed in a checkerboard pattern. The trenches have an oval shape wherein the diameter in a first direction 96 is smaller than the diameter in the second direction 97. In the lower left portion of FIG. 10B the sizes of the memory cells to be formed are indicated. As can be seen, the length of each of the memory cells is approximately 4×F, wherein F denotes the minimal structural feature size which may be obtained by the technology used. Moreover, the width of each of the individual memory cells is approximately 2×F. Accordingly, the total area of a memory cell amounts to approximately 8×F×F.

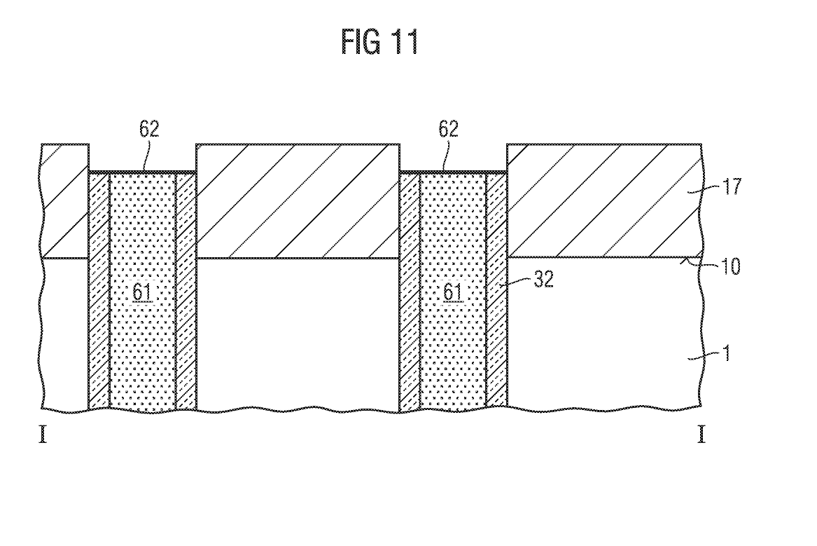

Starting from the structure illustrated in FIG. 10A, first, an etching process is performed so as to etch the upper portion of each of the isolation collars 32. Thereafter, the sacrificial filling 61 is recessed by a commonly used etching method. Thereafter, an oxidation process is performed so as to provide a thin silicon dioxide layer 62 having a thickness of approximately 1 to 3 nm. The resulting structure is illustrated in FIG. 11. As can be seen, the surface of the sacrificial filling 61 is covered with the silicon dioxide layer 62.

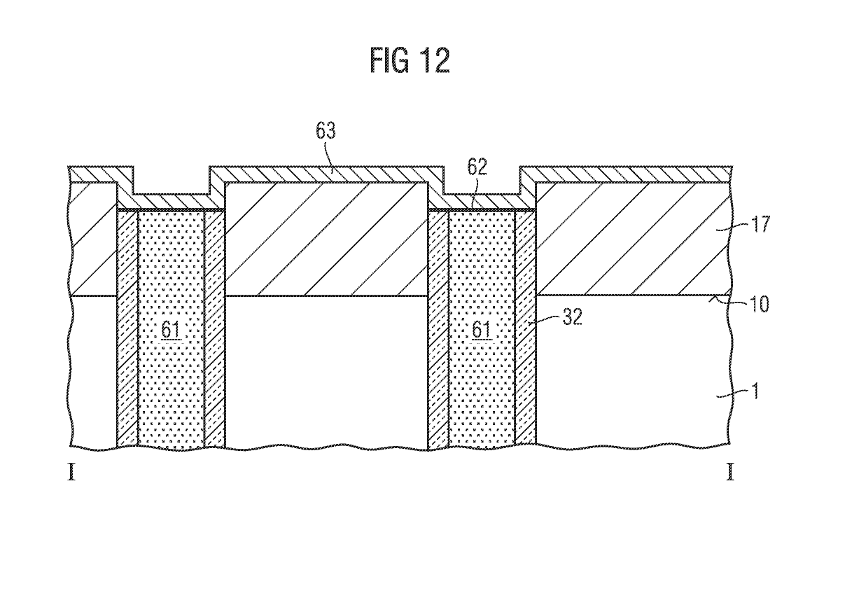

Thereafter, an undoped amorphous silicon layer 63 having a thickness of approximately 10 to 15 nm is deposited. For example, the amorphous silicon layer 63 may have a thickness of 12 to 14 nm. The resulting structure is illustrated in FIG. 12.

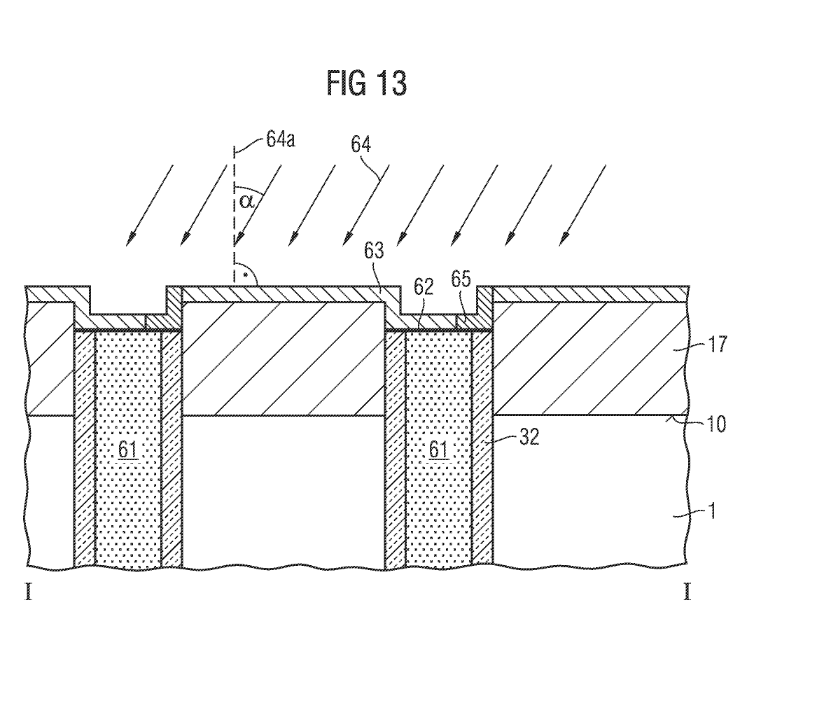

In the next process, a tilted ion implantation process 64 is performed. During this ion implantation process, an angle α of the ion beam 64 with respect to the normal on the substrate surface 64a may be approximately 5 to 30°. During this ion implantation process part of the ion beam is shadowed by the protruding portions of the silicon nitride layer 17 and amorphous silicon layer 63. Accordingly, predetermined portions of the undoped amorphous silicon layer will be doped whereas other predetermined portions remain undoped. For example, this ion implantation process may be performed with a p-dopant, for example BF₂-ions. The resulting structure is illustrated in FIG. 13. As can be seen from FIG. 13, portions 65 of the amorphous silicon layer 63 remain undoped, these portions being adjacent to a left hand edge of each of the protruding silicon nitride layer portions 17.

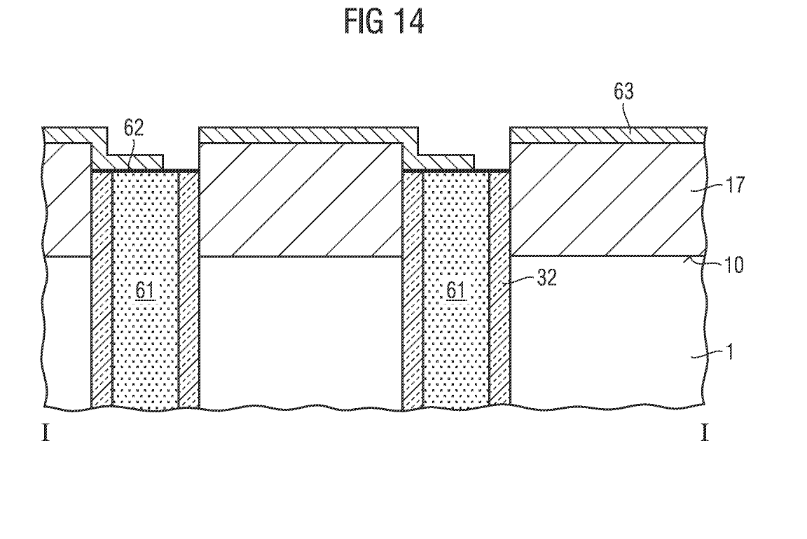

An etching process for etching the undoped amorphous silicon selectively with respect to doped amorphous silicon is performed. For example, this may be accomplished by etching with NH₄OH. The resulting structure is illustrated in FIG. 14. As can be seen, on the right hand side of each of the trenches the undoped amorphous silicon layer 63 is removed.

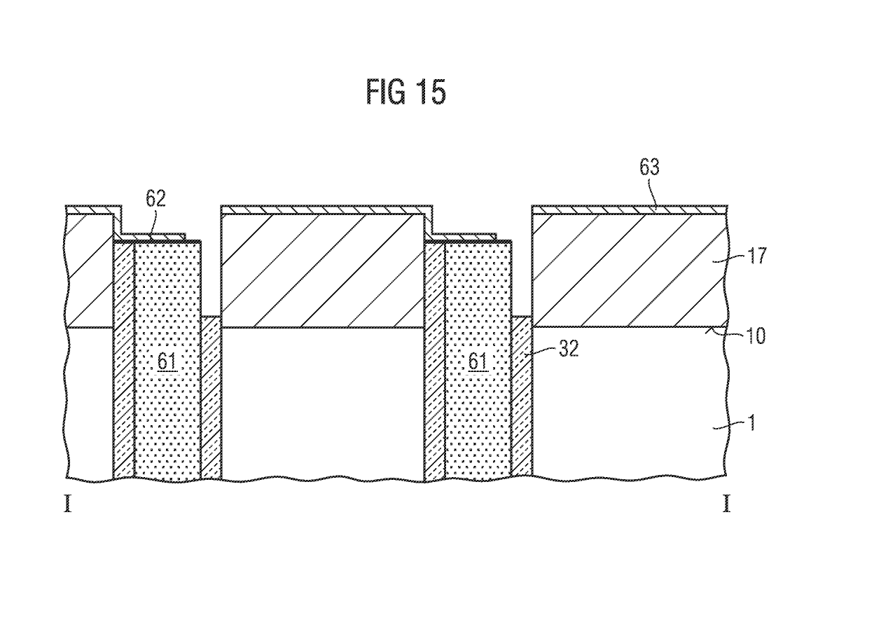

Thereafter, an etching process is performed which etches silicon dioxide selectively with respect to polysilicon. As a result, the collar portion 32 is recessed at those portions which are not covered with a silicon layer 63. In particular, this etching process is performed so that the collar is not recessed to a position below a position which is beneath the surface 10 of the semiconductor substrate. For example, approximately 85 to 115 nm may be etched. The resulting structure is illustrated in FIG. 15. As can be seen, in the right hand portion of each of the trenches 33, the collar is recessed, so that the resulting surface of the collar is disposed above the substrate surface 10. Moreover, the thickness of the amorphous silicon layer 63 is reduced.

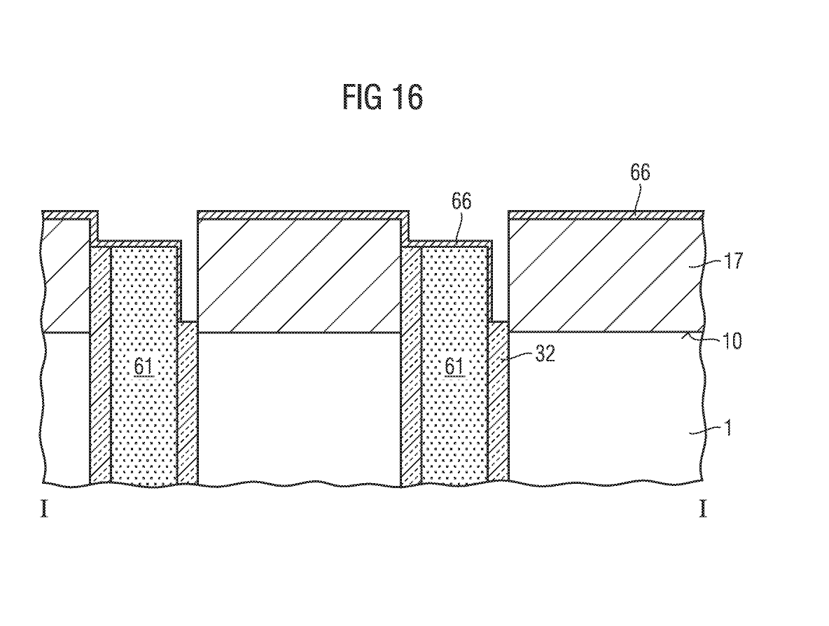

After performing a pre-cleaning process, so as to remove polymer residuals, an oxidation process is performed so as to provide the silicon dioxide layer 66. In particular, this oxidation process oxidizes the amorphous doped silicon layer 63 to result in the silicon dioxide layer 66. The resulting structure is illustrated in FIG. 16.

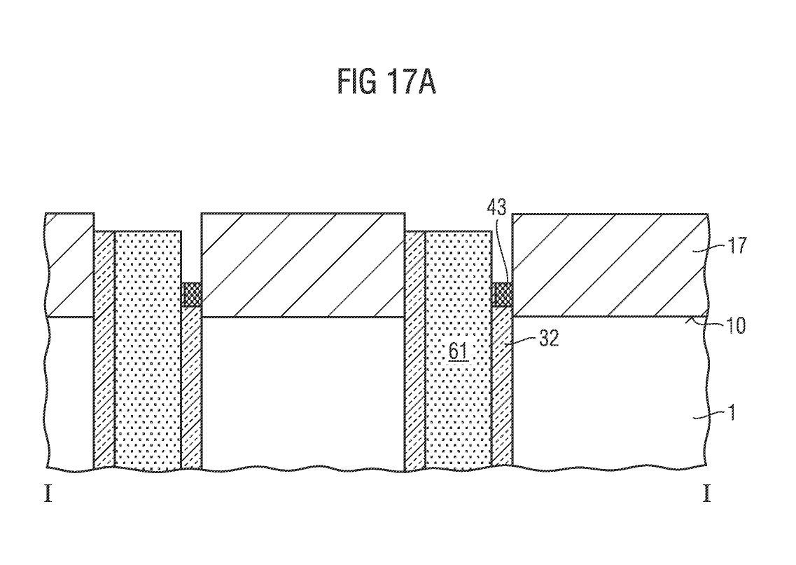

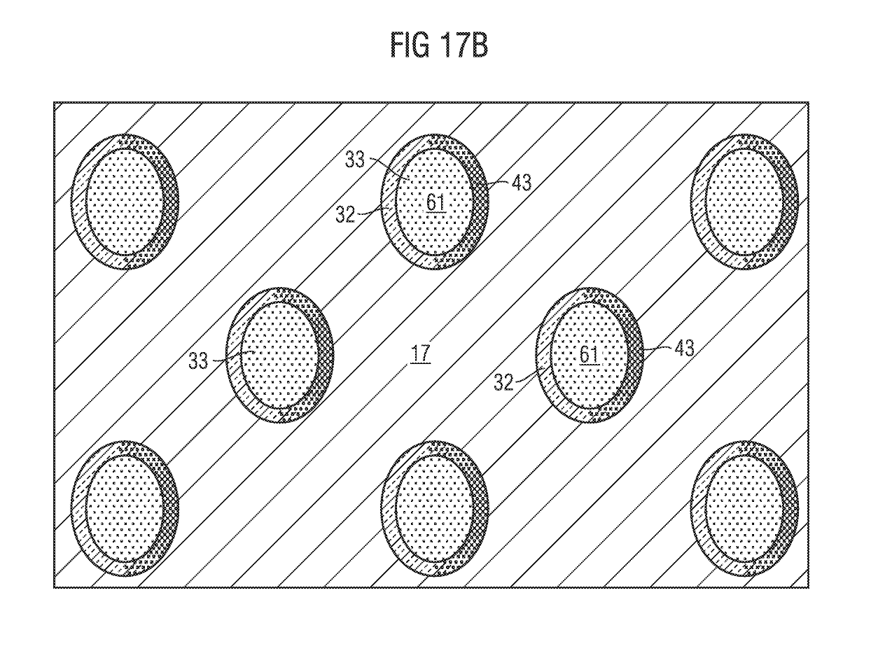

In the next process a conductive layer is deposited. For example, the conductive layer may comprise any material which might be suitable for a surface strap formation. By way of example, WSiₓ (tungsten silicide) may be used as the conductive strap material. Thereafter, a recessing process is performed so as to etch the conductive material. As a result, only a portion of the conductive material remains above the recessed portion of the collar 32. For example, when WSiₓ is taken as the conductive material, the WSiₓ may be wet etched with a suitable etchant such as a mixture of H₂O, H₂O₂ and NH₄OH. Alternatively, the WSiₓ may be etched dry with SF₆ chemistry. The resulting structure is illustrated in FIG. 17A. As can be seen, a conductive strap material 43 is provided in a portion between the sacrificial filling 61 and the silicon nitride layer portion 17. The conductive strap material is entirely disposed above the substrate surface 10.

FIG. 17B illustrates a plan view of the structure illustrated in FIG. 17A. As can be seen, the conductive strap material 43 is provided on one side of each of the trenches 33. On the other side of each of the trenches 33, the collar 32 extends to the surface.

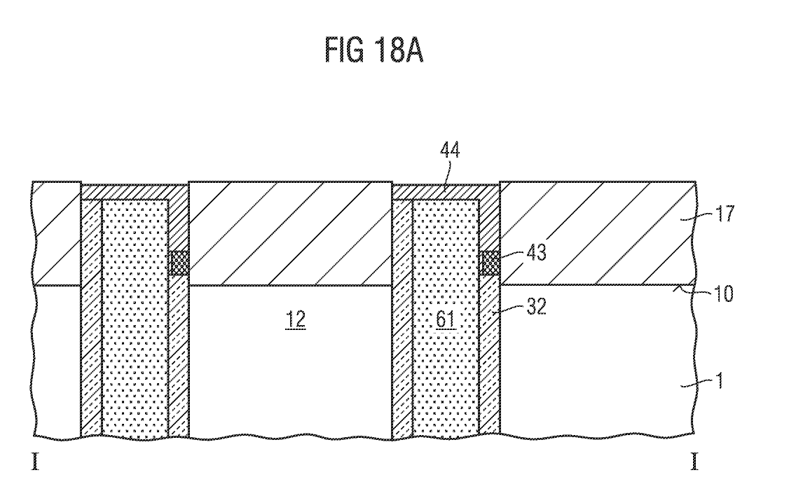

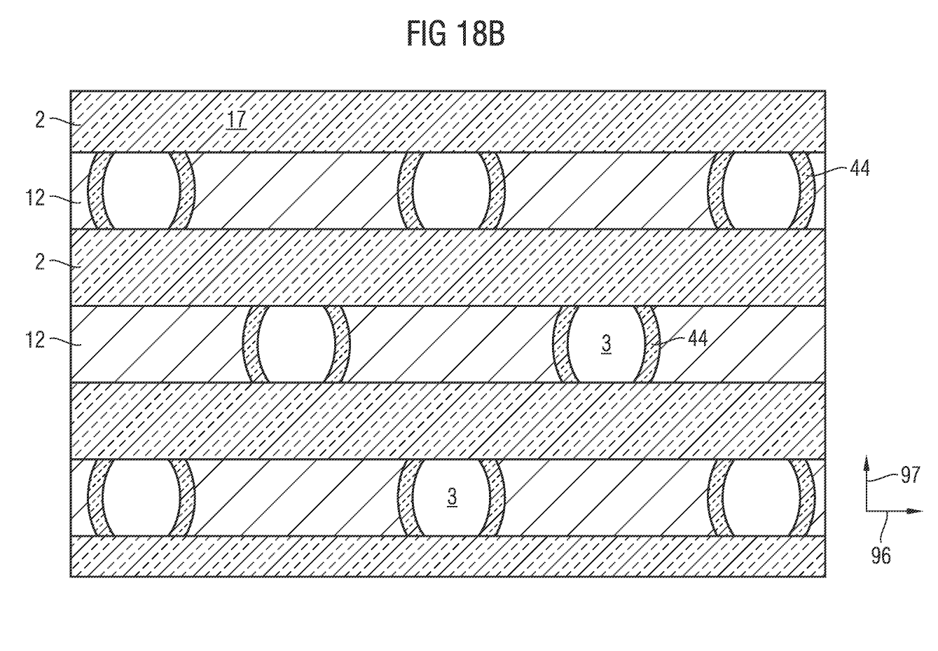

Thereafter, isolation trenches 2 are defined in a manner as is conventional. In particular, the isolation trenches are photolithographically defined and etched. The isolation trenches 2 extend before and behind the illustrated drawing plane illustrated in FIG. 18A, for example. The isolation trenches extend in a direction which is parallel to the direction along which the cross-sectional view illustrated in FIG. 18A is taken. By etching the isolation trenches 2, active areas 12, which are disposed between two adjacent isolation trenches are defined. After defining the isolation trenches 2, an oxidation process is performed. Thereby, also the surface of the sacrificial filling 61 is covered with a silicon dioxide layer. In addition, the isolation trenches are filled with an insulating material, followed by a CMP step. As a result, the surface of the sacrificial filling 61 is covered with the silicon dioxide layer 44, as is illustrated in FIG. 18A.

FIG. 18B illustrates a plan view of the resulting structure. As can be seen, a plurality of isolation trenches 2 is provided so as to extend in a first direction 96. Between adjacent isolation trenches, active areas 12 are formed. The active areas 12 also extend in the first direction 96. Trench capacitors 3 are positioned in the active areas, so as to isolate adjacent memory cells which are disposed in one row.

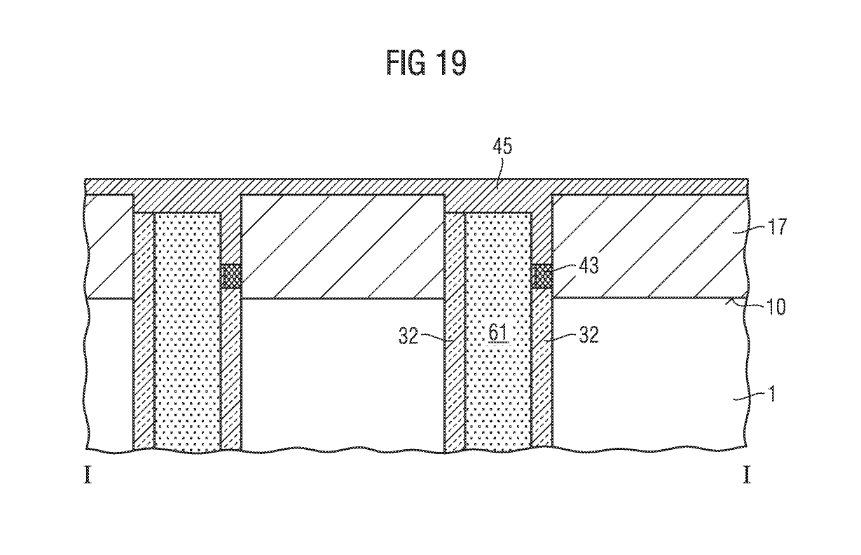

Thereafter, a silicon dioxide liner 45 is deposited on the entire surface. The resulting structure is illustrated in FIG. 19.

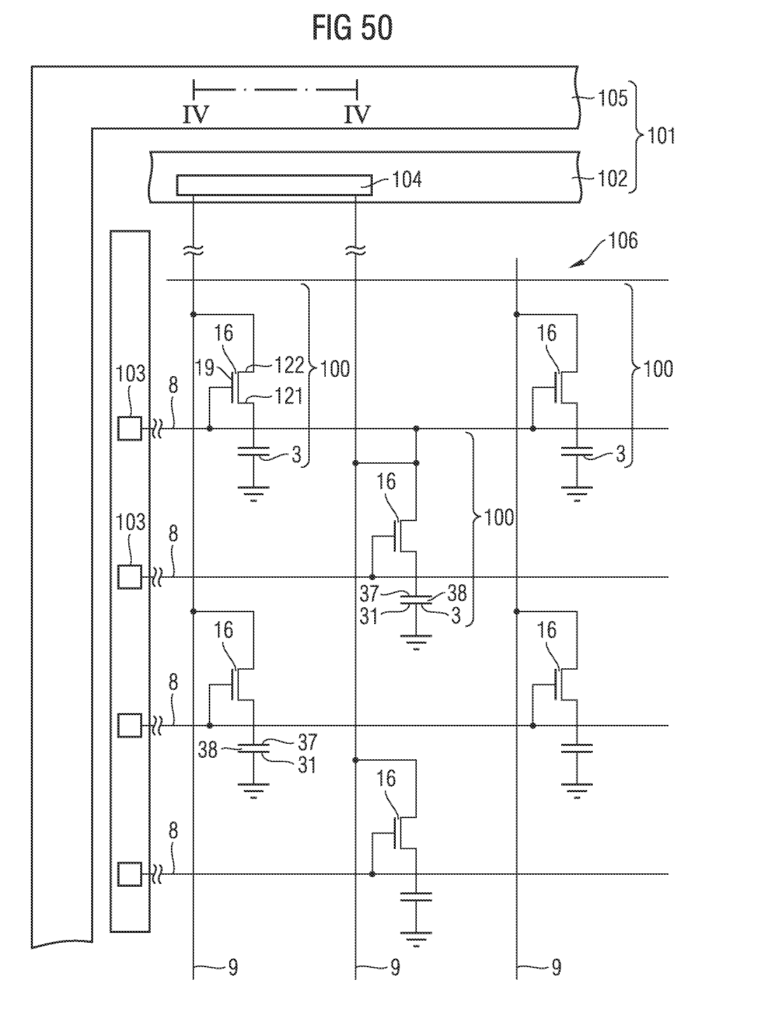

As will be explained later with reference to FIG. 50, a memory device generally includes a memory cell array having a plurality of memory cells, as well as a peripheral portion. For example, a plurality of transistors is disposed in the peripheral portion. Generally, it is desirable to process the array portion as well as the peripheral portion by the same process. Up to now, all processes have been likewise performed in the peripheral portion, taking appropriate photolithographic masks for defining the individual structures.

During the next processes, the whole peripheral portion will be protected by the silicon dioxide liner 45. Accordingly, a resist material is applied on the entire surface. The resist material (not illustrated) is selectively opened in the array portion leaving the peripheral portion covered. Thereafter, an etching process for etching silicon dioxide is performed so that the surface of the array portion now is exposed. Then, the resist material is removed from the peripheral portion. As a result, the entire peripheral portion is protected by the silicon dioxide liner 45, whereas the array portion is uncovered.

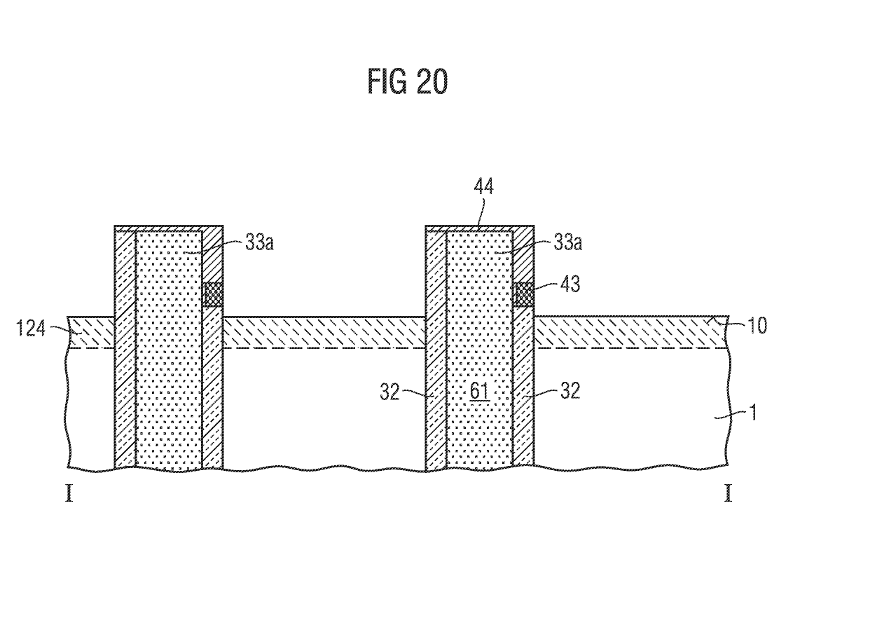

Thereafter, the silicon nitride layer 17 is removed. Moreover, an ion implantation process with n dopants is performed so as to provide the doped portion 124. The resulting structure is illustrated in FIG. 20. As can be seen, now protruding trench structures 33a are present. The trench structures protrude from the substrate surface 10. The sacrificial filling 61 is covered with the silicon dioxide layer 44 on the top side thereof. A conductive strap material 43 is provided at the lateral portion so as to enable an electrical contact. The conductive strap material 43 is positioned above the substrate surface 10. The doped portion 124 is disposed adjacent to the substrate surface 10.

In the next process, an angled ion implantation process using n-dopants such as phosphorous or arsenic is performed. The angle β between the tilted ion beam 46 and the normal 64a to the substrate surface is approximately 5 to 30°. During this ion implantation process, the protruding trench portions 33a serve as a shadowing mask so as to provide asymmetric doped portions 42. In particular, these asymmetric doped portions 42 are provided at the position at which a bitline contact is to be formed in a later process step. Due to the asymmetric doped portion 42, the dopant concentration of the second source/drain region 122 will be increased with respect to the dopant concentration of the first source/drain region 121.

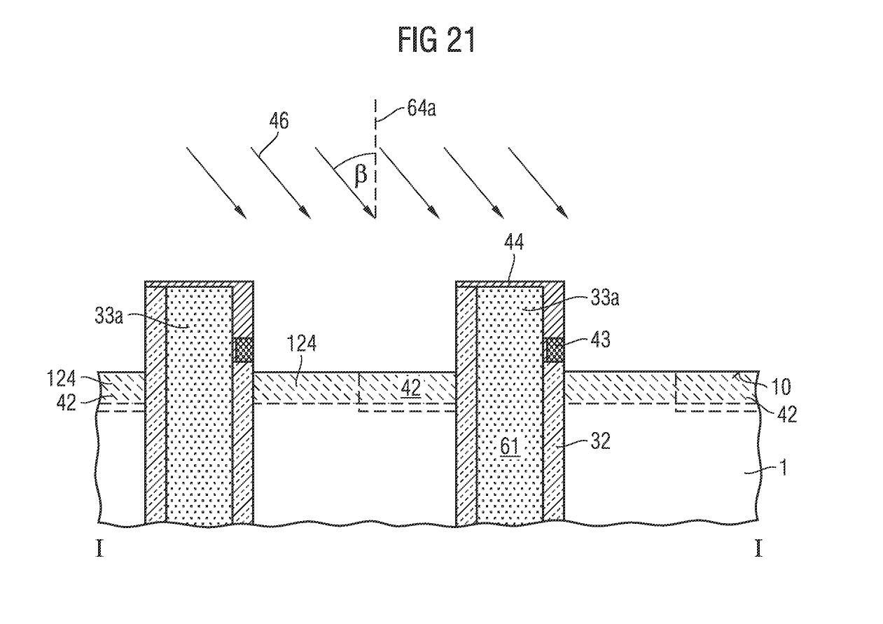

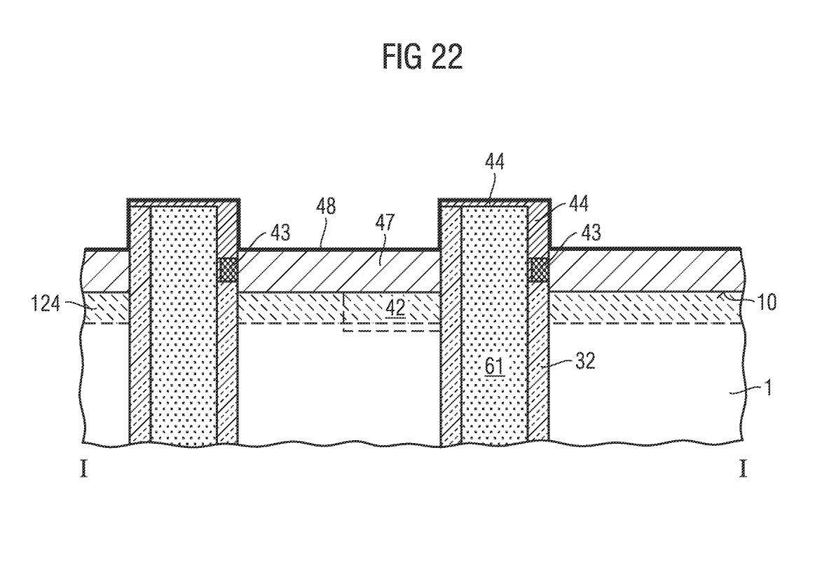

The resulting structure is illustrated in FIG. 21. As can be seen, the doped portion 42 is provided at a position adjacent to the left hand side of each of the trenches 33. In the next process, a conductive layer, in particular, a doped silicon layer having a thickness of approximately 25 to 35 nm is deposited. Then, an etching process is performed so as to recess the doped polysilicon layer. Thereafter, a silicon nitride liner 48 is deposited. For example, the silicon nitride liner may have a thickness of approximately 2 nm. The resulting structure is illustrated in FIG. 22. As can be seen, now, a doped polysilicon layer 47 is directly adjacent to the substrate surface 10. Moreover, the doped polysilicon layer 47 is connected with the conductive strap material 43. Moreover, the silicon nitride layer 48 is formed on the surface of the polysilicon layer 47, the silicon nitride layer 48 also covering the silicon dioxide layer 42.

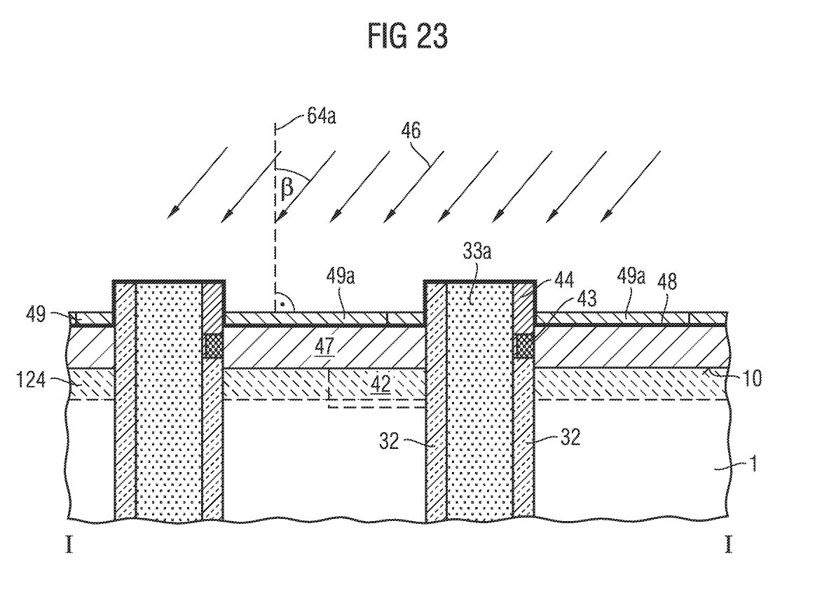

In the next process, an undoped amorphous silicon layer having a thickness of approximately 20 to 40 nm is deposited. Thereafter, the amorphous silicon layer 49 is recessed so as to have an appropriate thickness. Then, an angled ion implantation process is performed so as to provide a bitline contact. For example the angle β between the ion beam 46 and a normal 64a to the substrate surface may be approximately 5 to 30°. This implantation process is performed using a p-dopant, for example BF₂-ions. Accordingly, also during this implantation process, the protruding trench portions 33a serve as a shadowing mask so that only predetermined portions of the amorphous silicon layer become doped, whereas the portions of the amorphous silicon layer 49 which are adjacent to the left hand side of each of the trenches 33 remain undoped. The resulting structure is illustrated in FIG. 23. As can be seen, now the left hand portion of each of the layers 49 is a doped silicon portion 49a whereas the right hand portion remains undoped.

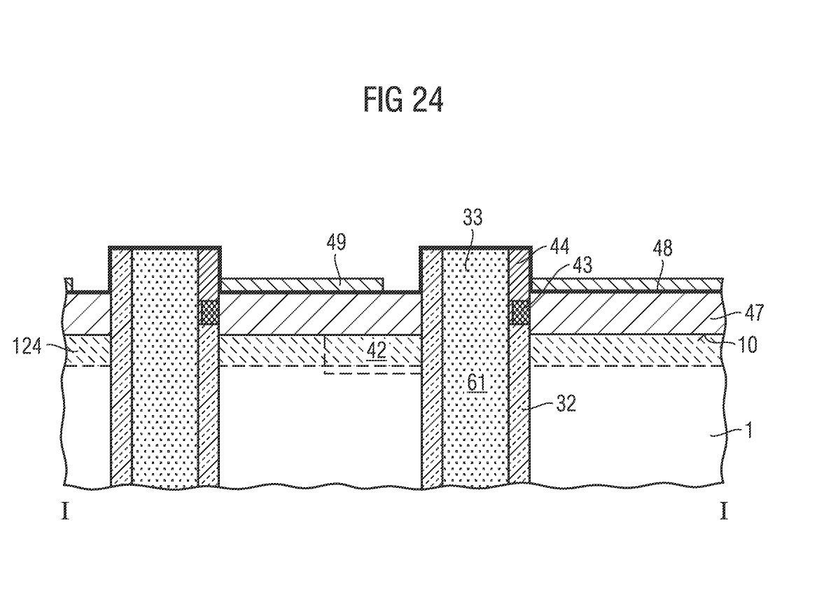

In the next process, an etching process which etches undoped amorphous silicon selectively with respect to doped amorphous silicon is performed. For example, NH₄OH may be taken as an etchant. The resulting structure is illustrated in FIG. 24. As can be seen, part of the amorphous silicon layer 49 is removed at a position adjacent to the left hand side of each of the trenches 33.

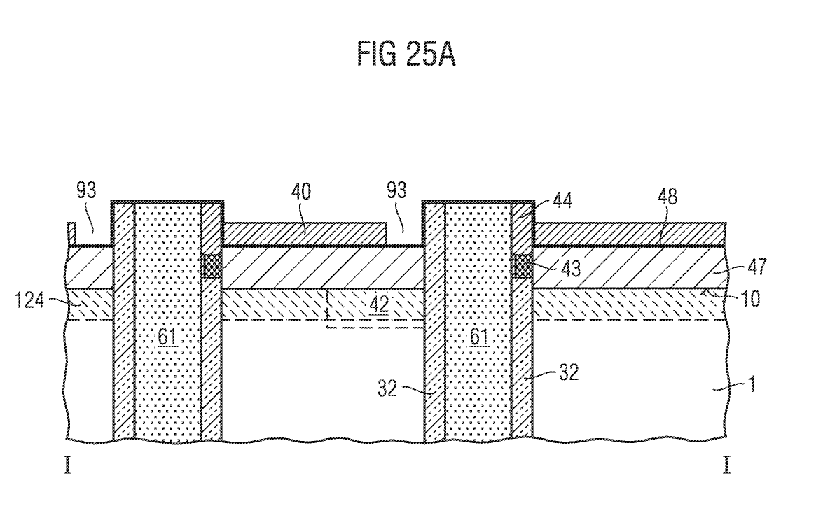

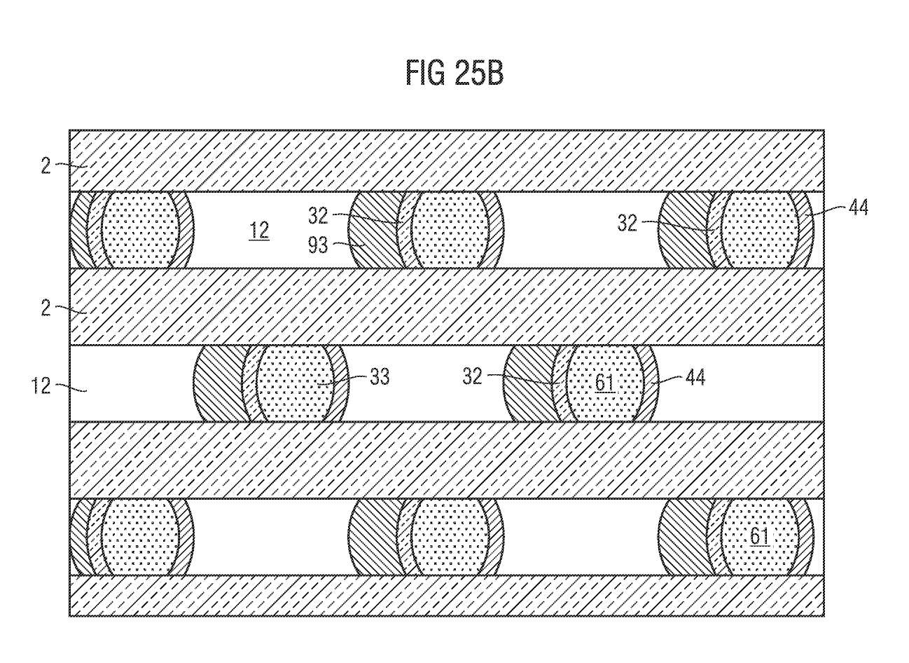

Thereafter, an oxidation process is performed so as to oxidize the amorphous doped silicon layer to a silicon dioxide layer 40. The resulting structure is illustrated in FIG. 25A. As can be seen, a bitline contact opening 93 is formed at a position adjacent to one side of each of the trenches 33. Moreover, the remaining surface is covered with a silicon dioxide layer 40.

FIG. 25B illustrates a plan view of the resulting structure. As can be seen, the bitline contact openings 93 are formed on one side of each of the trenches 33. On the other side of each of the trenches 33 the conductive strap material 43 is provided, the conductive strap material being covered with the silicon dioxide portion 44.

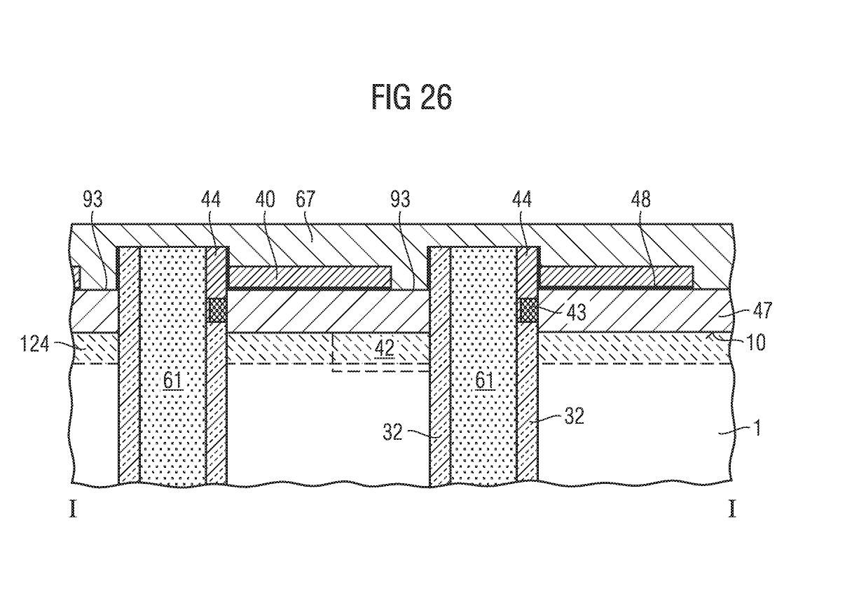

In the next process, the silicon nitride layer is etched selectively with respect to silicon dioxide. As a result, the silicon nitride layer is removed from the bitline contact opening 93. Then, an n-doped polysilicon layer 67 is deposited. For example, the polysilicon layer 67 may have a thickness of 20 nm. Alternatively, the polysilicon layer 67 may be deposited at a higher thickness, followed by a CMP step. For example, the polysilicon layer 67 may be doped with phosphorous. The resulting structure is illustrated in FIG. 26. As can be seen, now, the entire surface is covered with the doped polysilicon layer. The doped polysilicon layer 67 is in electrical contact with the doped polysilicon layer 47. In particular, the doped polysilicon layer 67 is connected with the doped polysilicon layer 47 at the bitline contact opening portion 93.

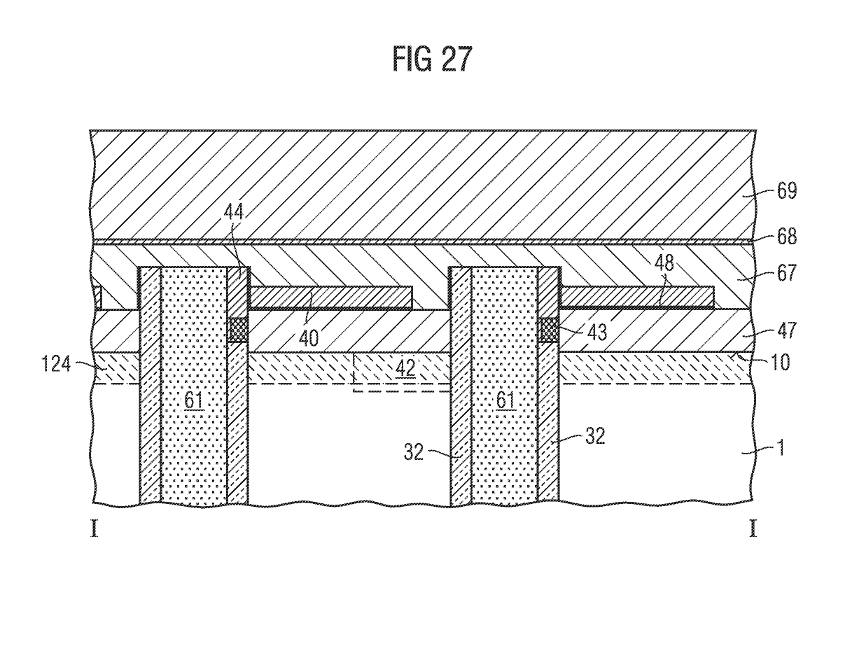

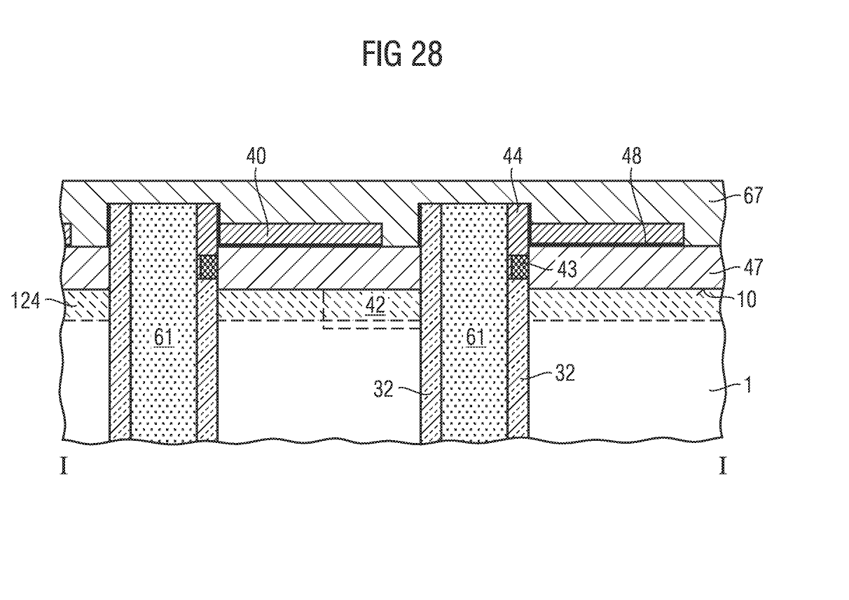

In the next processes, various processes for processing the peripheral portion are performed. In particular, first, the peripheral portion is opened, followed by various etching and ion implantation processes. Thereafter, the silicon dioxide layer is formed so as to cover the peripheral portion as well as the array portion. Thereafter, an undoped polysilicon layer having at thickness of approximately 70 to 90 nm is deposited. The undoped polysilicon layer acts as a part of the gate electrode stack in the peripheral portion. A cross-sectional view of the array portion is illustrated in FIG. 27. As can be seen, on the surface of the doped polysilicon layer 67, a silicon dioxide layer 68 is formed. This silicon dioxide layer 68 acts as a gate oxide layer in the peripheral portion. Moreover, on the surface of the silicon dioxide layer 68, the undoped polysilicon layer 69 is formed. Thereafter, another resist material is applied and patterned so that only the array portion is uncovered. Then, an etching process is performed so as to etch silicon material selectively with respect to silicon dioxide. Thereafter, the resist material is removed from the peripheral portion. Thereafter, an etching process of etching silicon dioxide material selectively with respect to silicon is performed. As a result, in the array portion the structure illustrated in FIG. 28 is obtained. As can be seen, now the surface of the doped polysilicon layer 67 is uncovered.

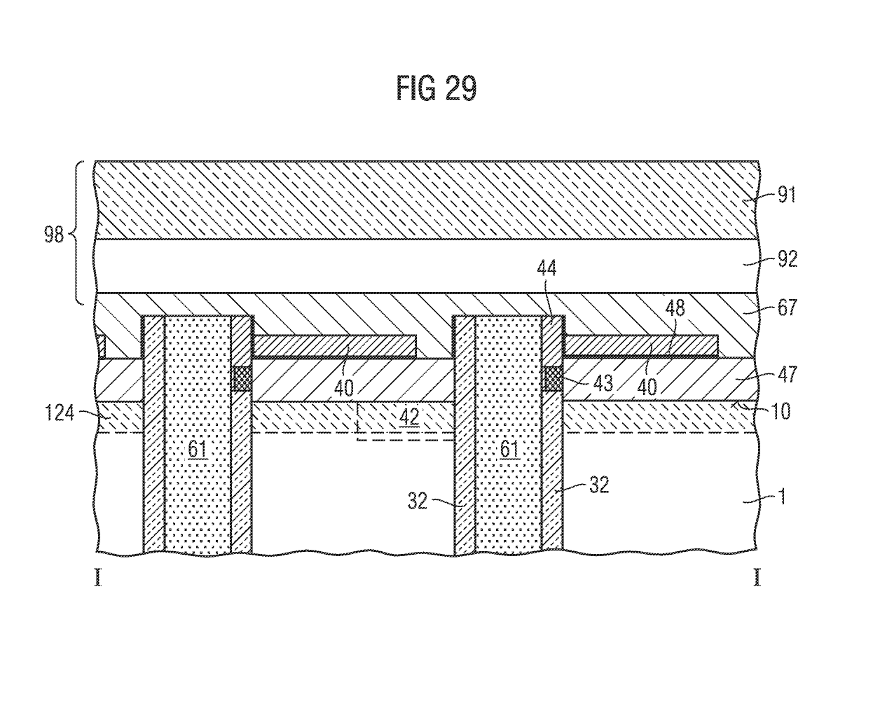

In the next process, the remaining layers for providing the bitlines in the array portion and the gate electrodes in the peripheral portions are provided. For example, a TiN layer 92 may be deposited, followed by a silicon nitride layer 91. The resulting structure is illustrated in FIG. 29. As can be seen, on top of the doped polysilicon layer 67, now the conductive layer 92 and the silicon nitride layer 91 are provided.

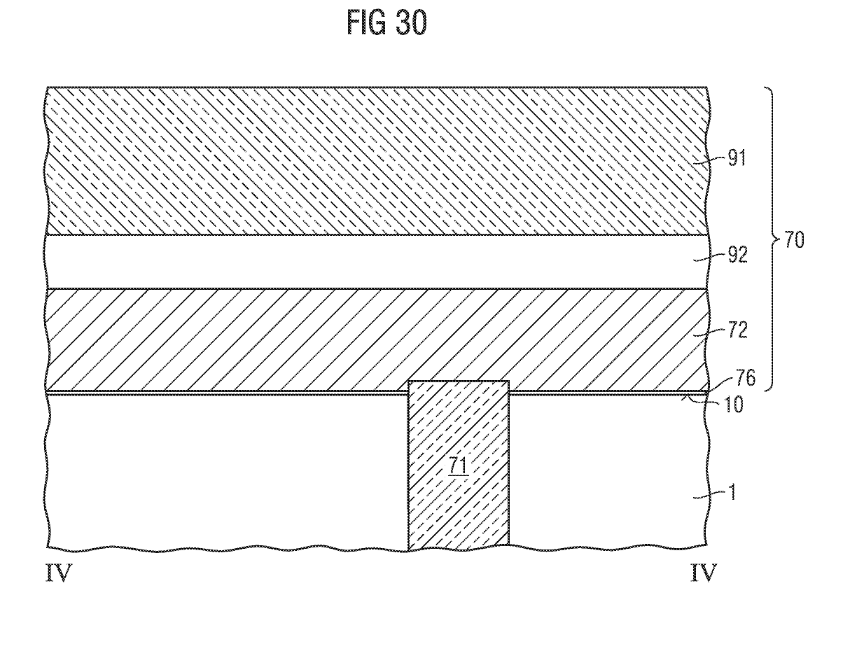

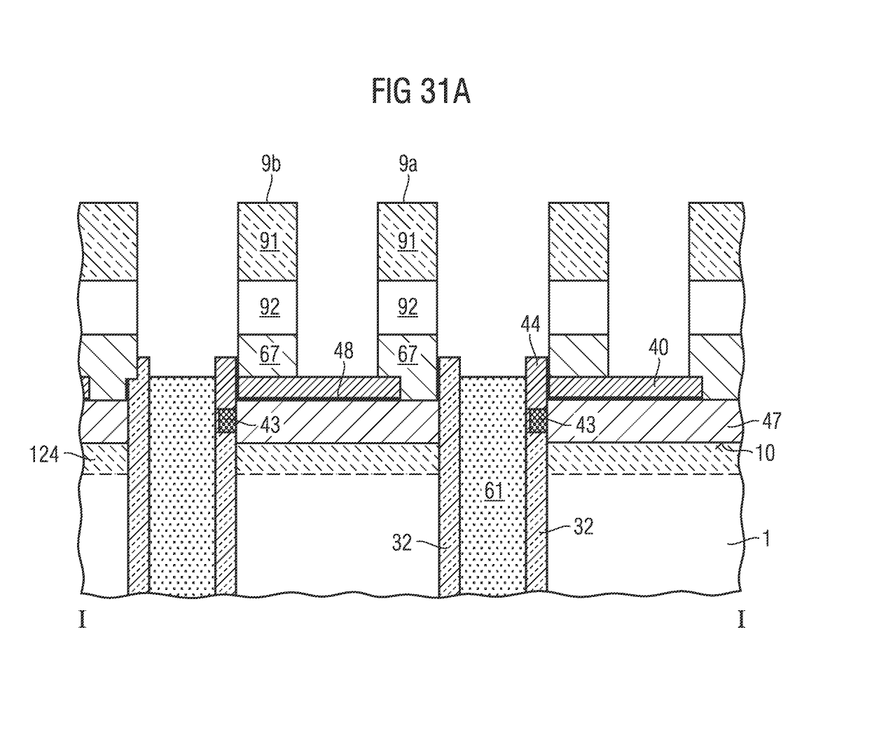

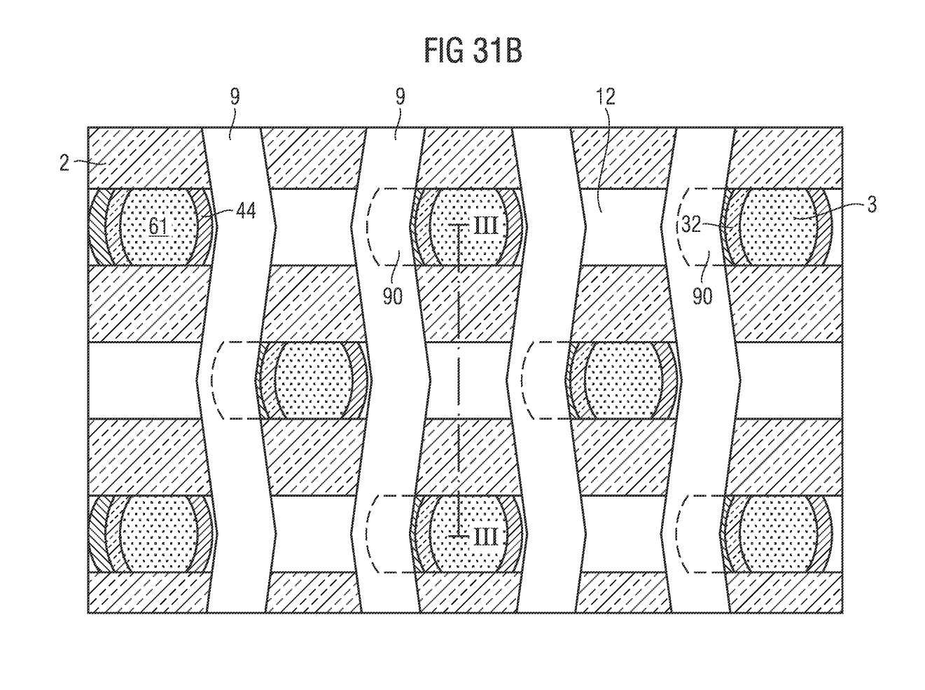

FIG. 30 illustrates a cross-sectional view of the peripheral portion which is taken between IV and IV, as can be also seen from FIG. 50. As can be seen, in the peripheral portion, peripheral isolation trenches 71 are provided. On the surface 10 of the semiconductor substrate 1, a gate oxide layer 76 is provided. On top of the peripheral gate oxide layer the peripheral gate stack including the peripheral polysilicon layer 72, the TiN layer 92 and the silicon nitride layer 91 is provided. Thereafter, a patterning process is performed so as to pattern the peripheral gate stack and the bitline stack of the array portion 98 using an appropriate mask. In particular, in the array portion, bitlines are formed, and in the peripheral portion gate electrodes are formed. The layer stack is etched so that in the array portion the structure illustrated in FIG. 31A is obtained. As can be seen, now single bitlines 9a, 9b are formed above the substrate surface 10. Each of the active bitlines 9a is in direct contact with the doped polysilicon layer 47.

FIG. 31B illustrates a plan view of the resulting structure. As can be seen, the bitlines 9 are patterned so that they need not necessarily be straight lines but may be as well angled lines. If the bitlines are implemented as angled bitlines, they can be routed along the trenches formed in the substrate surface so that the opening of the trenches is not covered by the bitlines. As can be seen, the bitlines are positioned in such a manner, that they are in contact with each of the bitline contacts 90.

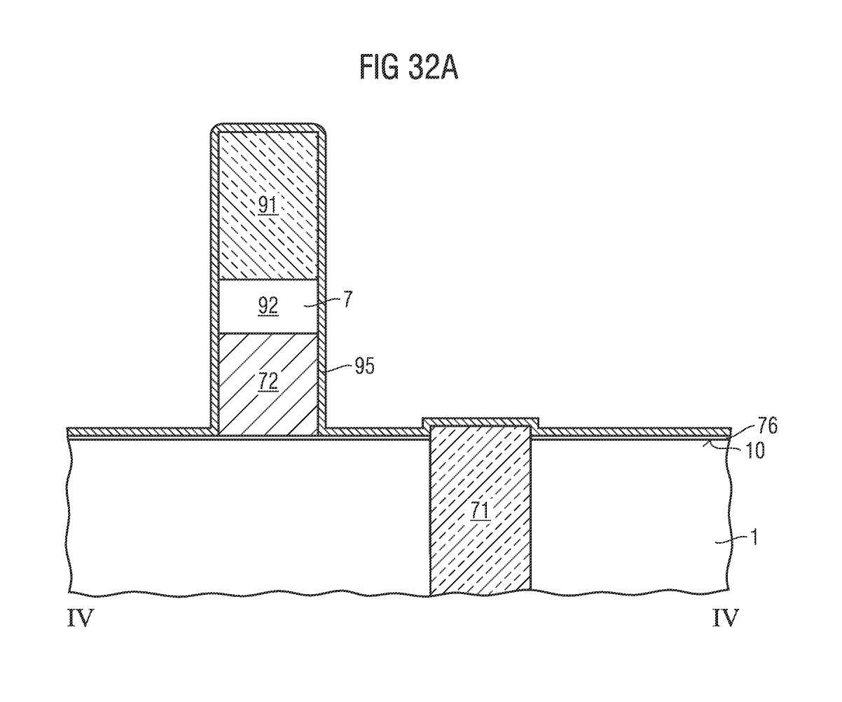

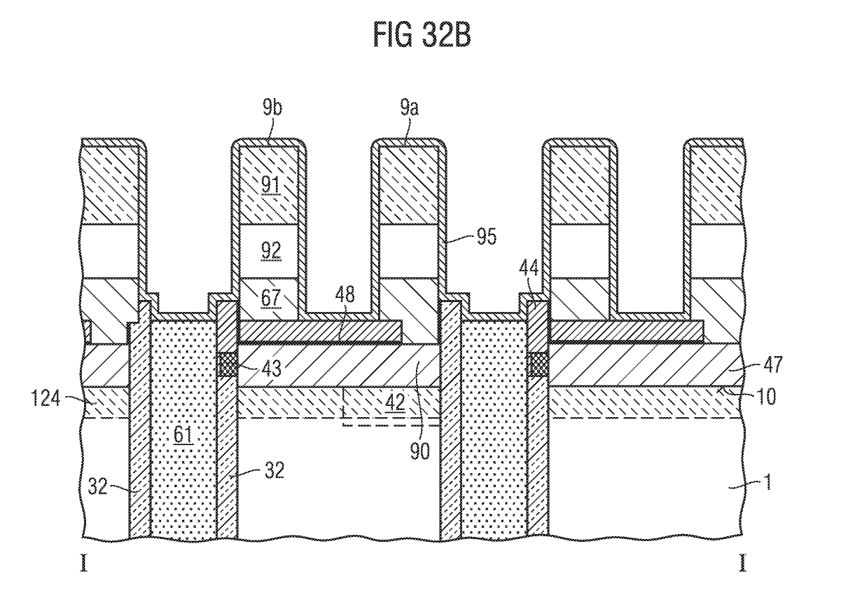

Since the peripheral polysilicon layer 72 has a larger thickness than the polysilicon layer 67 of the array portion, it is necessary to perform another etching process of etching polysilicon in the peripheral portion. Accordingly, the array portion is covered with a suitable resist material, and a process of etching silicon in the peripheral portion is performed. After removing the resist material from the array portion, a silicon nitride layer 95 having a thickness of approximately 2 to 5 nm is conformally deposited. A cross-sectional view of the resulting structure in the peripheral portion is illustrated in FIG. 32A. As can be seen, now, single peripheral gate electrodes 7 are defined. Moreover, the silicon nitride layer 95 is disposed so as to laterally protect the conductive layers of the peripheral gate electrode 7.

A cross-sectional view of the array portion of the resulting structure is illustrated in FIG. 32B. As can be seen, now, single bitlines 9a, 9b are formed, a silicon nitride layer 95 being conformally deposited. Accordingly also in the array portion, the conductive layers are laterally protected by the silicon nitride layer 95.

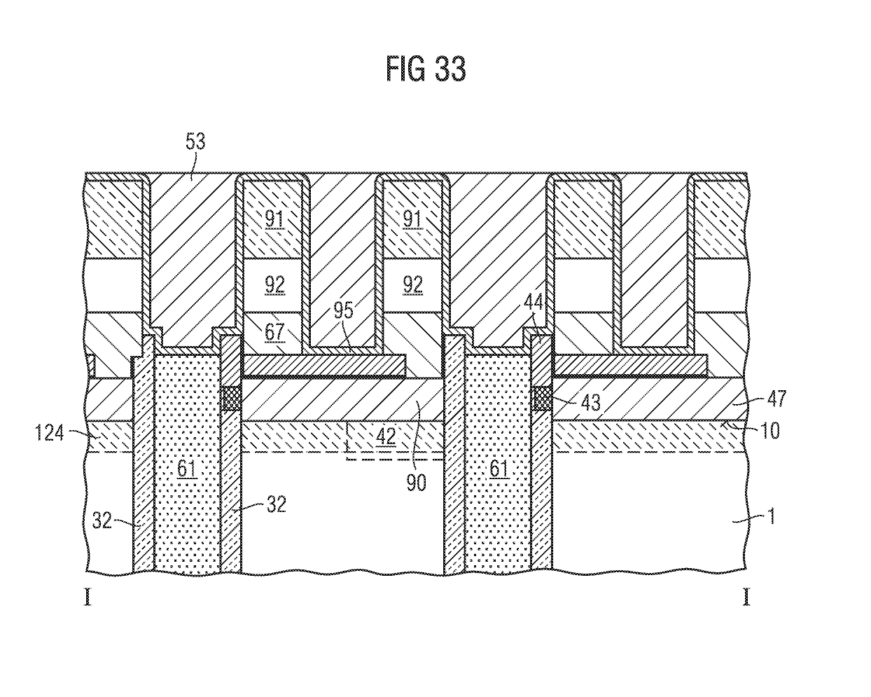

In the next process, a polysilicon layer 53 is deposited and recessed so that the surface of the polysilicon layer 53 is at the same height as the surface of the silicon nitride layer 91. The recessing may be accomplished by etching or by a CMP step. A cross-sectional view of the resulting structure is illustrated in FIG. 33. As can be seen from FIG. 33, now the spaces between adjacent bitlines 9 are filled with the polysilicon material 53.

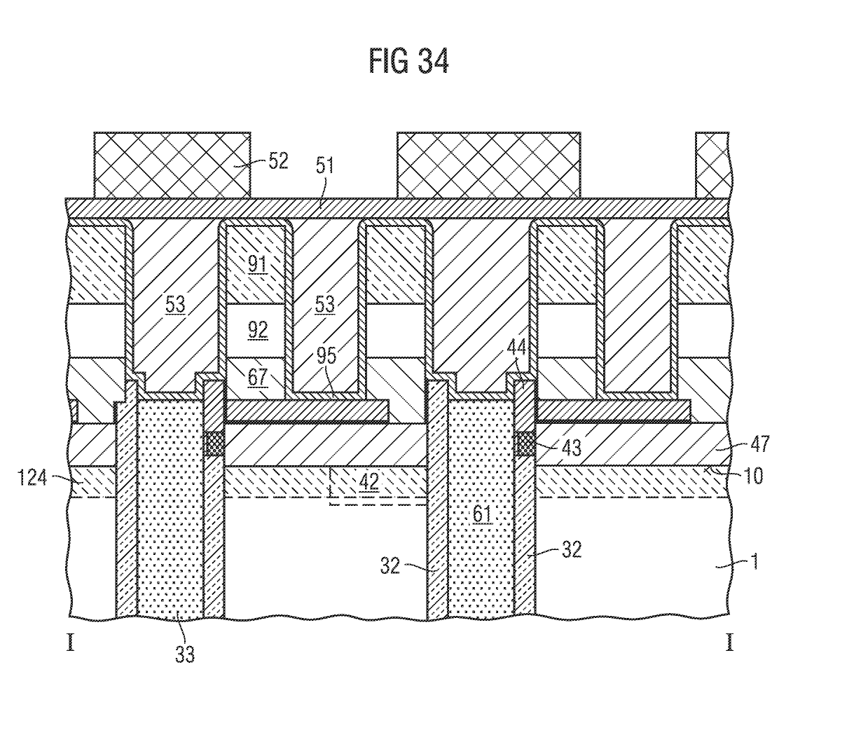

Then, a first hard mask layer 51 which may for example be a silicon dioxide layer having a thickness of approximately 15 to 25 nm is deposited, followed by a carbon hard mask layer 52. Then, the carbon hard mask layer 52 is patterned by a commonly known method. For example, the carbon hard mask layer 52 may be patterned using a mask having oval, circular or openings in the shape of segments of lines. As a result, predetermined portions of the silicon dioxide layer 51 are uncovered. The resulting structure is illustrated in FIG. 34. As can be seen, now the portions above each of the trenches is covered with the carbon hard mask layer portions 52, while portions of the polysilicon layer 53 above the transistor to be formed are unexposed.

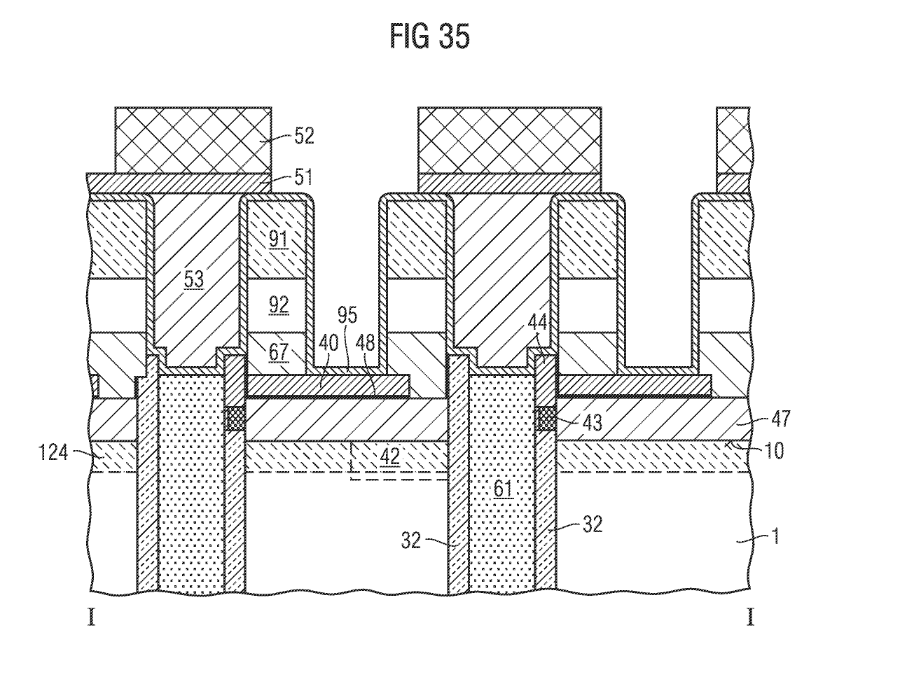

In the next process, first, silicon dioxide is etched selectively with respect to silicon and silicon nitride, this etching stopping on top of the polysilicon layer 53 in the exposed portions. Thereafter, polysilicon is etched selectively with respect to silicon nitride, this etching stopping on top of the horizontal portions of the silicon nitride layer 95. The resulting structure is illustrated in FIG. 35. As can be seen, now, the polysilicon layer 53 is removed from the portions at which the gate electrode is to be formed.

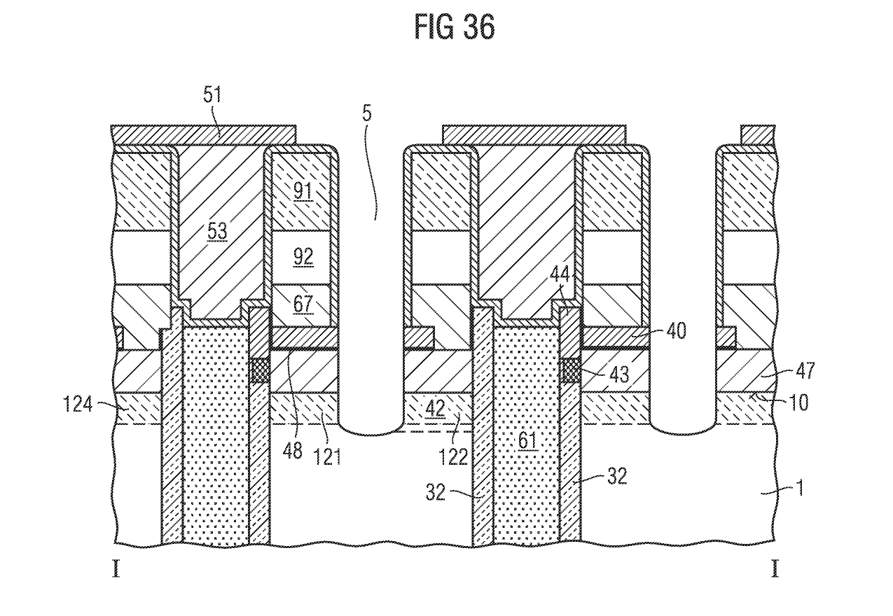

Thereafter, several etching processes are performed, taking the carbon hard mask layer 52 as well as the silicon nitride cap layer 91 as an etching mask. For example, the exposed portions of the silicon nitride layer 95 are etched, as is common, followed by a process of etching the silicon dioxide layer 40. After etching the exposed portion of the silicon nitride layer 48, a selective etching process is performed so as to etch silicon material selectively to silicon nitride and silicon dioxide. For example, this etching process may be performed so as to form a gate groove 5 which extends to a depth of approximately 10 to 200 nm, for example, 10 to 100 nm below the substrate surface 10. Thereafter, the remaining portions of the carbon hard mask 52 are removed. The resulting structure is illustrated in FIG. 36. As can be seen from FIG. 36, now gate grooves 5 are formed in the semiconductor substrate surface 10. The gate groove 5 extends to a depth of approximately 10 to 100 nm and separates the first source/drain region 121 from the second source/drain region 122.

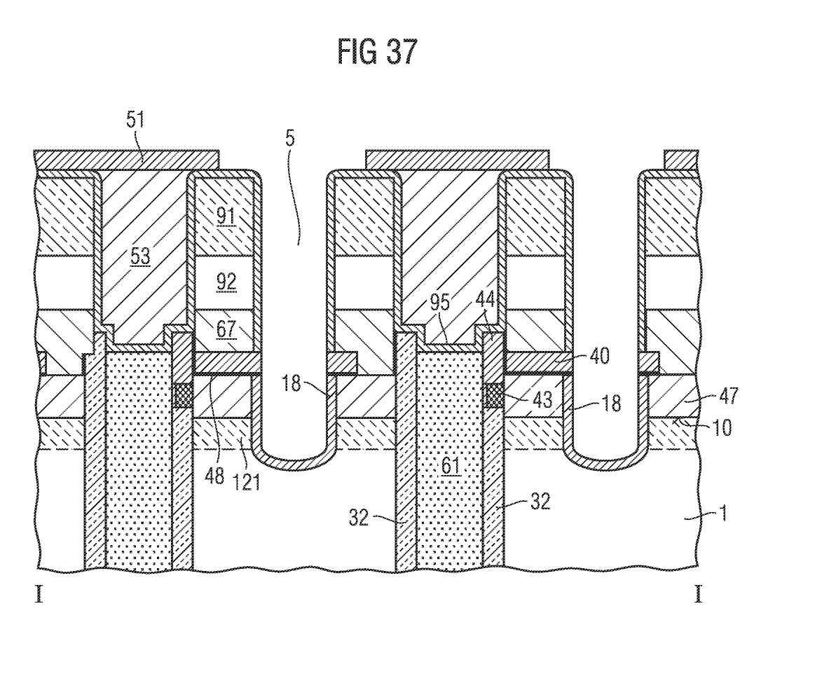

In the next process, an oxidation process is performed so as to provide a silicon dioxide spacer 18 on the sidewall of each of the gate grooves 5. The resulting structure is illustrated in FIG. 37. As can be seen, in the lower portion of the gate groove, in which the gate groove is adjacent to silicon material, a silicon dioxide spacer 18 is formed.

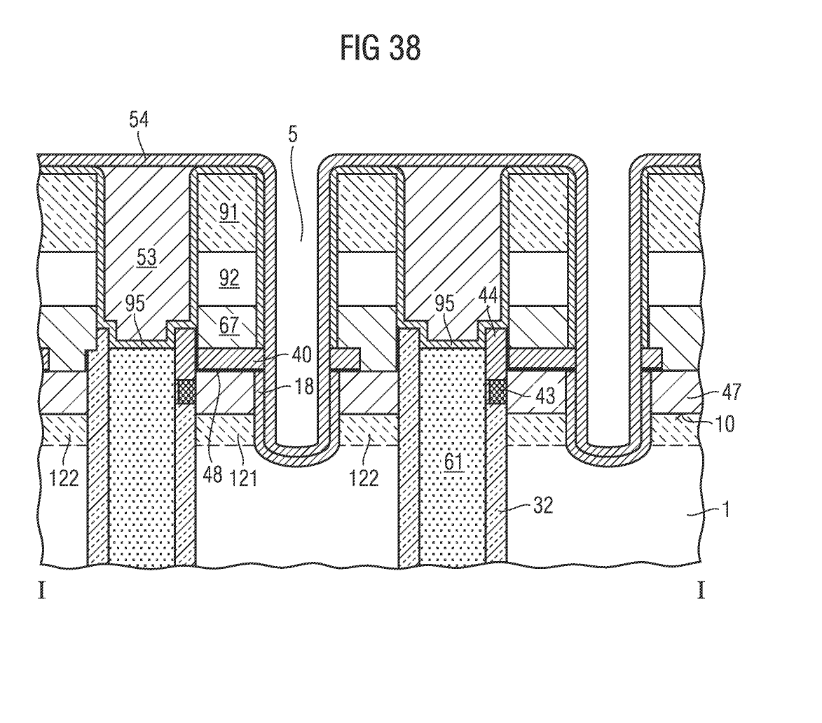

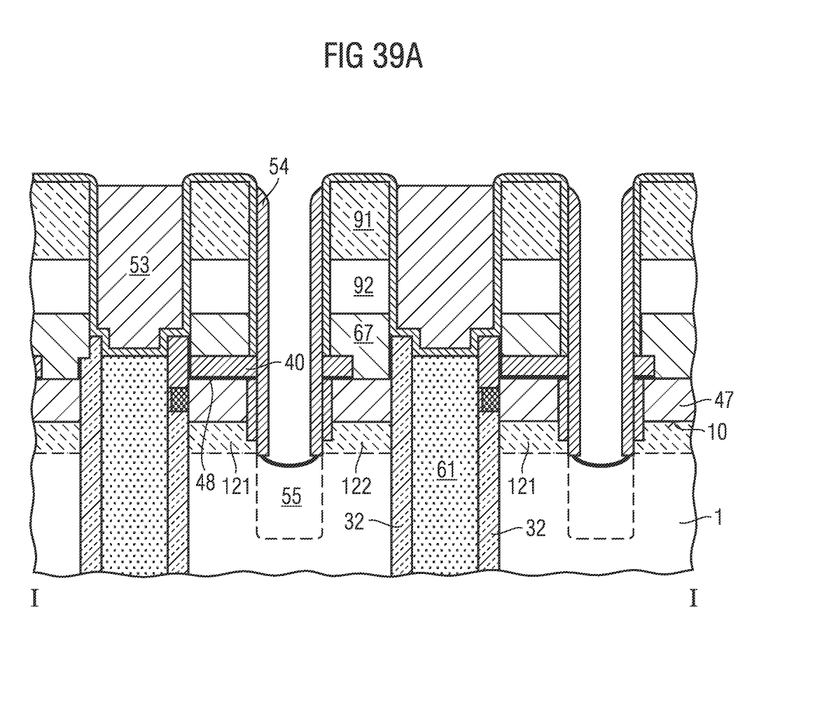

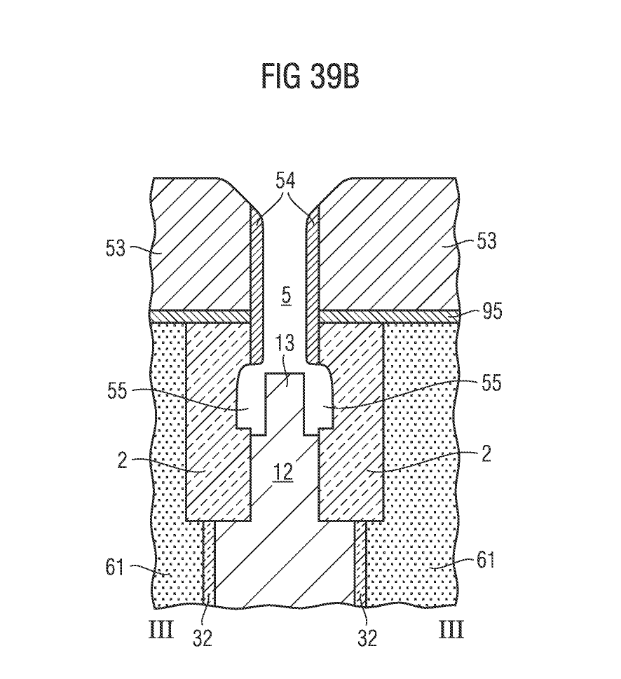

Thereafter, a further silicon dioxide layer 54 having a thickness of approximately 8 to 12 nm is deposited. The resulting structure is illustrated in FIG. 38. As can be seen, now a silicon dioxide layer 54 is conformally formed on the entire surface. Then, an etching process for etching the plate-like portions 55 of the gate electrode is performed. In particular, pockets 55 are defined in the isolation trenches at a position adjacent to the gate groove. For example, this may be accomplished by an anisotropic etching process which etches silicon dioxide selectively with respect to silicon and silicon nitride. As a result, the structure illustrated in FIG. 39A is obtained. As can be seen, now, the horizontal portions of the silicon dioxide layer 54 are removed. Moreover, in a plane before and behind the illustrated plane of the drawing, pockets 55 are defined in the isolation trenches.

A process of etching silicon material isotropically may be performed so as to further thin the active region.

FIG. 39B illustrates a cross-sectional view which is taken in a direction which is perpendicular to the direction illustrated in FIG. 39A. For example, the cross-sectional view of FIG. 39B is taken between III and III, as can be seen from FIG. 31B. As can be gathered from FIG. 39B, isolation trenches 2 delimit an active area 12 at two sides thereof. Pockets 55 are defined in a portion of the isolation trenches 2 which is adjacent to the active area, the pockets 55 being adjacent to the gate groove 5. Accordingly, the active area 12 has the shape of a ridge 13, wherein the substrate material is enclosed by pockets 55 as well as the gate groove 5. For example, the pockets 55 may extend to a depth of approximately 50 to 80 nm, measured from the top surface of the ridge 13. As is further illustrated, the fin portion 13 of the active area 12, i.e. the portion of the active area in which the active area has the shape of a ridge is further thinned.

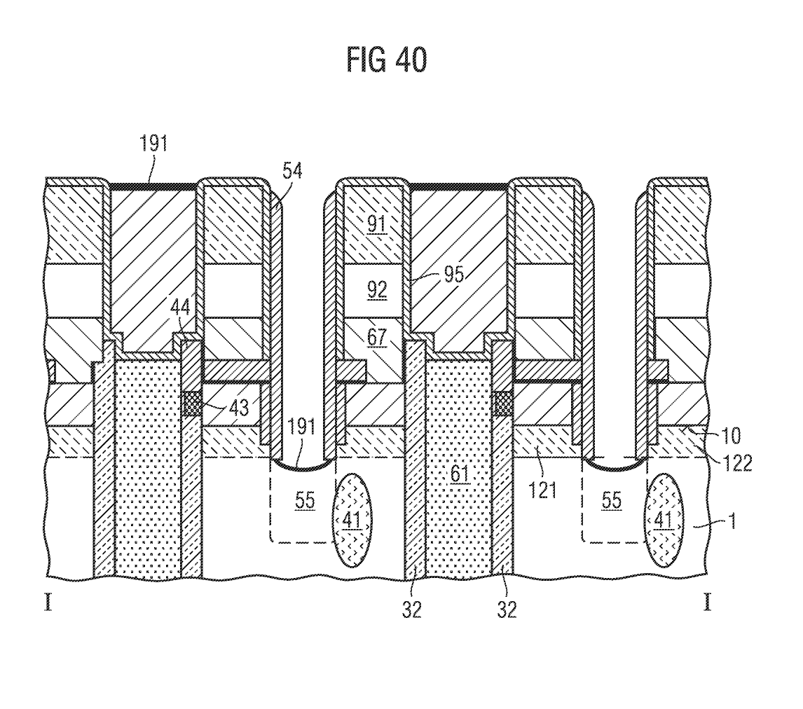

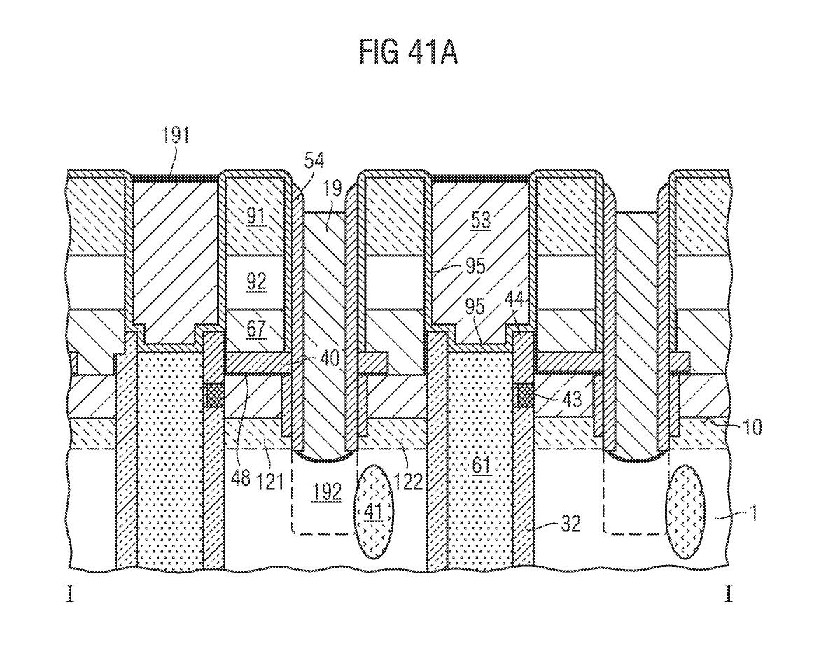

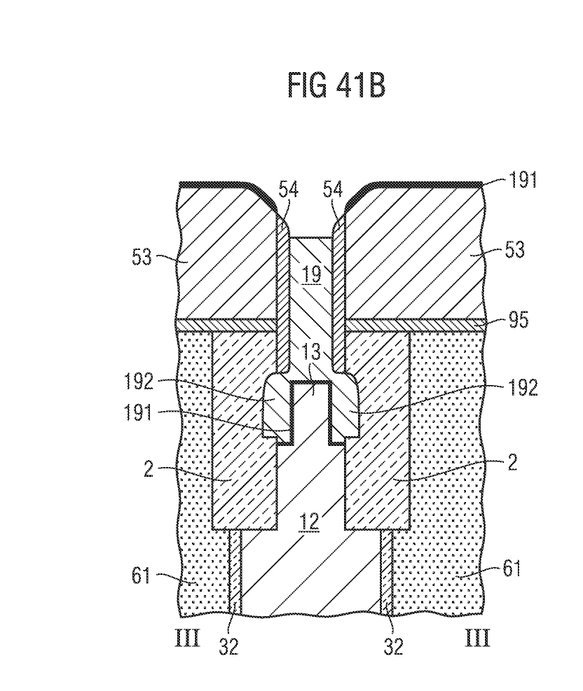

An angled implantation process with p dopants may be performed so as to provide the doped portion 41. For example, an angle of the ion beam with respect to a normal 64a to the substrate surface 10 may be approximately 3 to 8°. In particular, the doped portion 41 refers to the so-called anti-punch implant which is performed so as to avoid a punch-through, which means that the depletion regions of the first and second source/drain regions contact each other. Then, a gate insulating layer 191 is provided. For example, an oxidation process may be performed, so as to provide a silicon dioxide layer. A cross-sectional view of the resultant structure is illustrated in FIG. 40. As can be seen, on top of the polysilicon portions 53, now the gate insulating layer 191 is provided. Moreover, in the gate groove, the gate insulating layer is provided at the interface between gate groove and silicon substrate material. Thereafter, a gate material is deposited. For example, any material which is suitable as a gate electrode material may be deposited. Specific examples comprise metal or doped polysilicon. Then, the gate material is recessed so that the surface of the gate electrode material is below the topmost surface of the bitline cap layer 91. FIG. 41A illustrates a cross-sectional view of the resulting structure. As can be seen, now the gate groove 5 is filled with the gate electrode 19. The gate electrode 19 is shielded from the first and second source/drain regions 121, 122, by the thick silicon dioxide spacer 54. Moreover, as is indicated by broken lines, plate-like portions 192 of the gate electrode are provided.

FIG. 41B illustrates a cross-sectional view which is taken along III and III in a direction perpendicularly with respect to the cross-sectional view illustrated in FIG. 41A. As can be seen, now plate-like portions 192 of the gate electrode 19 are defined, the plate-like portions extending partially in the isolation trenches 2 as well as in the active region 12. The plate-like portions 192 are connected with the gate electrode formed in the gate groove. The active area 12 is insulated from the gate electrode 19 by a gate insulating layer 191.

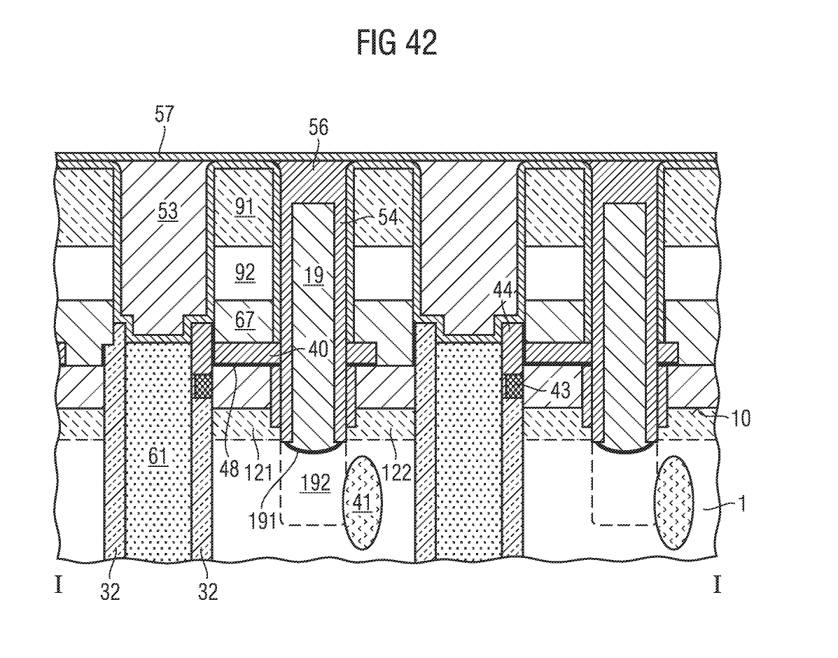

During the processes of forming the gate groove and the gate electrode, the peripheral portion has not been processed. Next, several processes are performed so as to further process the peripheral portion. For example, the polysilicon material 53 is removed, a silicon dioxide layer is deposited, a process of etching silicon dioxide selectively with respect to silicon is performed, several implantation processes are performed, and a silicon nitride liner 57 is deposited. FIG. 42 illustrates a cross-sectional view of the resulting structure in the array portion. As can be seen, now the entire surface is covered with the silicon nitride liner 57. Moreover, the upper portion of the gate electrode 19 is filled with a silicon dioxide layer 56.

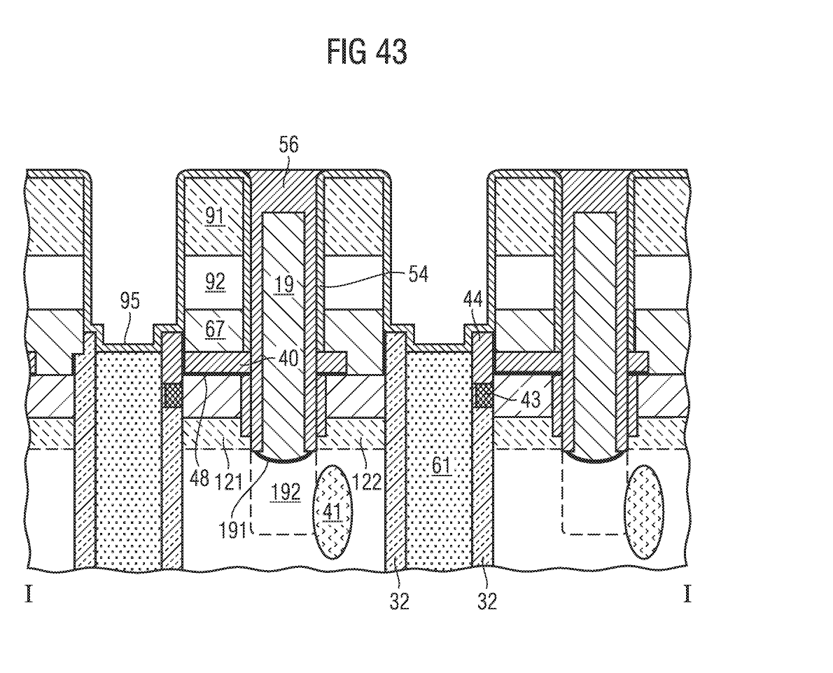

In the next processes, the sacrificial filling of the capacitor trenches will be removed and replaced by a capacitor dielectric as well as a second capacitor electrode. Accordingly, first a suitable resist material is applied and patterned so that the peripheral portion is entirely covered with a resist material, leaving the array portion uncovered. Thereafter, a dry etching process of etching silicon nitride is performed so as to remove the silicon nitride liner 57 from the array portion. Thereafter, the resist material is removed from the peripheral portion. As a result, the entire peripheral portion is covered with a silicon nitride liner 57. Then, an etching process for etching silicon material selectively with respect to silicon nitride is performed so as to remove the remaining portions of the polysilicon filling 53. The resulting structure is illustrated in FIG. 43. As can be seen, the sacrificial filling 61 is only covered with a silicon nitride liner 95, and the polysilicon filling 53 is removed.

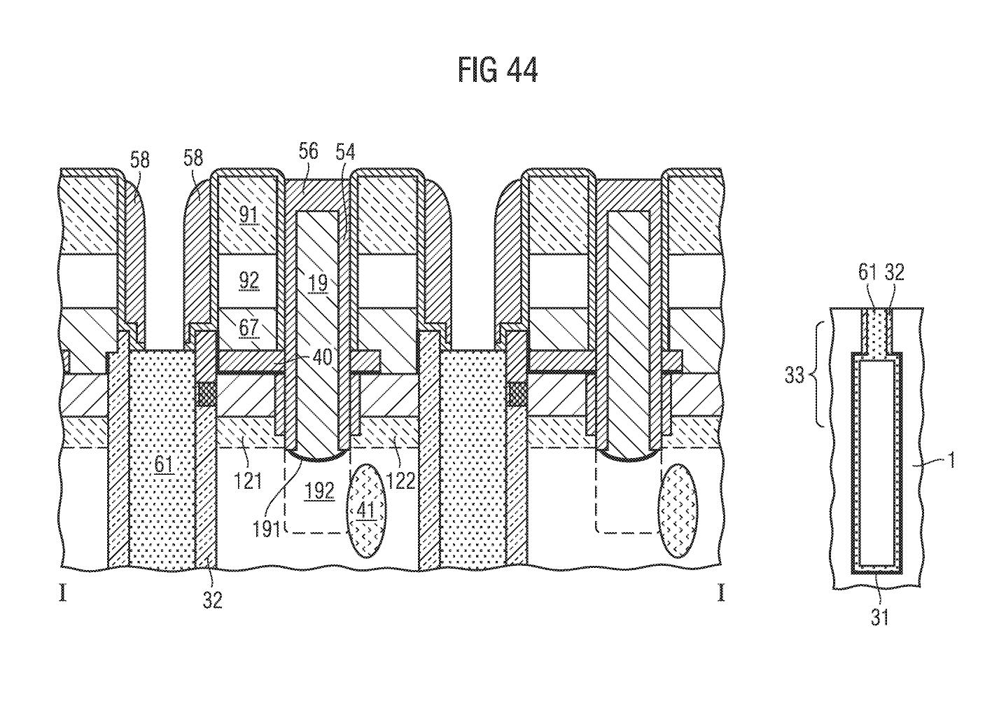

In the next process, the sidewalls of each of the bitlines will be protected by an additional silicon dioxide spacer 58. To this end, first, a silicon dioxide layer is conformally deposited, followed by an anisotropic etching step. Thereby, the horizontal portions of the silicon dioxide layer will be etched. As a result, spacers 58 having a thickness of approximately 4 to 7 nm remain on the sidewall portions of the bitlines. During this anisotropic etching process also the horizontal portions of the silicon nitride layer 95 will be etched. The resulting structure is illustrated in FIG. 44. As can be seen, now the surface of the sacrificial filling 61 is uncovered.

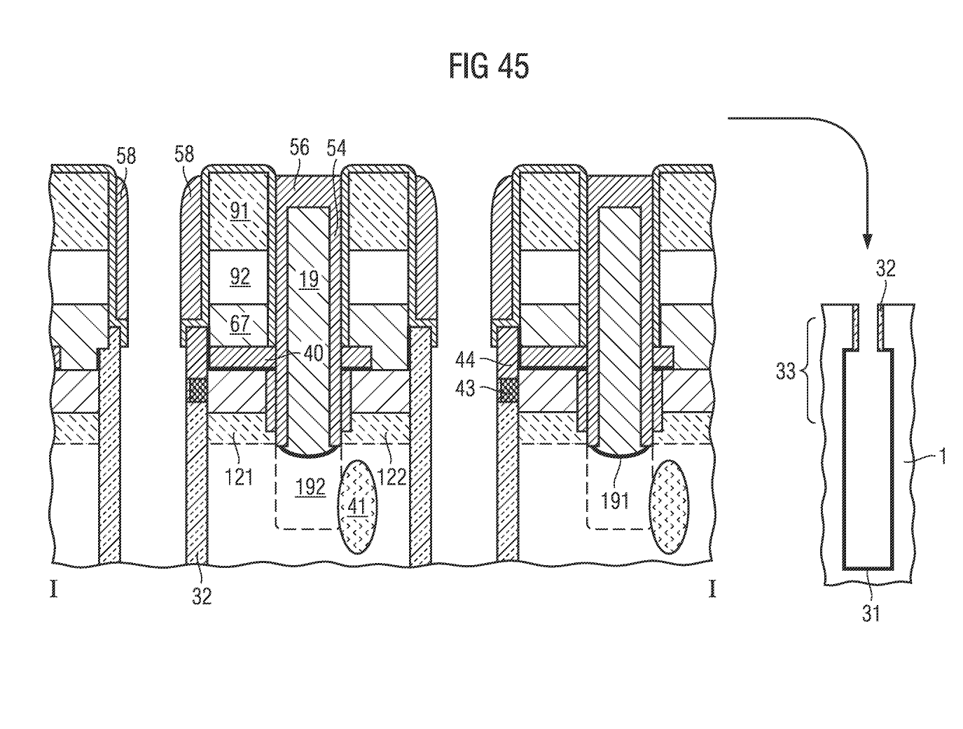

Thereafter, the sacrificial filling 61 will be removed from the trenches 33. For example, this may be accomplished by a dry or a wet isotropic etching step. As a result, as is indicated in FIG. 45, the sidewalls of the trench are no longer covered with the sacrificial material, and the surface of the first capacitor electrode 31 is uncovered. The right-hand portion of FIG. 45 illustrates the trench 33 from which the sacrificial filling 61 is removed.

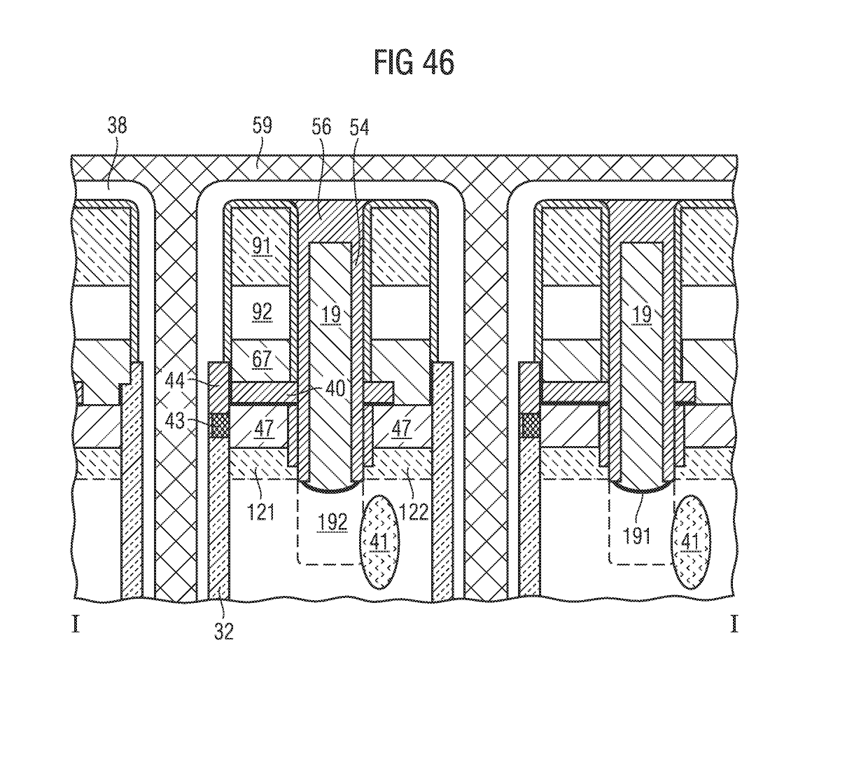

In the next process, the dielectric material forming the capacitor dielectric 38 is deposited. For example, a so-called high-k dielectric having a relative dielectric constant of at least 8, for example more than 20 and as a further example more than 30 may be deposited. For example, any of the dielectric materials as mentioned above may be deposited, having a thickness of 4 to 12 nm. Moreover, a resist material 59 is deposited. The resulting structure is illustrated in FIG. 46.

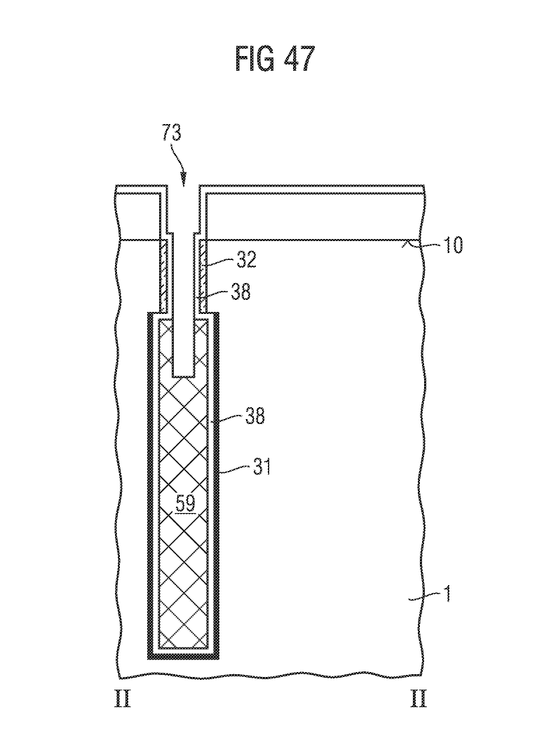

Thereafter, the resist material 59 is removed from the upper portion of the trench. For example, this may be accomplished, by a first isotropic etching process, followed by an anisotropic etching step. For example, these etching processes should be performed in that manner, that the collar portion of the trench is no longer covered with a resist material 59, whereas the lower trench portion which is disposed beneath the collar portion is covered with a resist material 59. FIG. 47 illustrates a cross-sectional view of the trench after this recess etching step. As can be seen from FIG. 47, a capacitor dielectric 38 is provided so as to cover the first capacitor electrode, the collar as well as the surface of the structure. The resist material 59 is recessed in such a manner, that the collar portion is uncovered whereas the portion of the trench which is disposed beneath the collar still is covered with the resist material. The position of the resist recess is denoted by reference numeral 73.

Thereafter, the dielectric material will be stripped from the upper portion of the trench. In particular, the dielectric material is removed from those portions which are not covered by the resist material 59. For example, this may be accomplished by wet etching. Optionally, in this process, also the remaining portion of the silicon oxide layer 44 is removed, this portion being adjacent to the lateral surface of the conductive strap material 43. Then, the resist material 59 is also removed, for example by wet etching. As a result, in the lower portion of the trench, which is disposed beneath the collar 32, the first capacitor electrode is disposed on the sidewalls of the trench, a dielectric layer 38 being disposed above the first capacitor electrode 31.

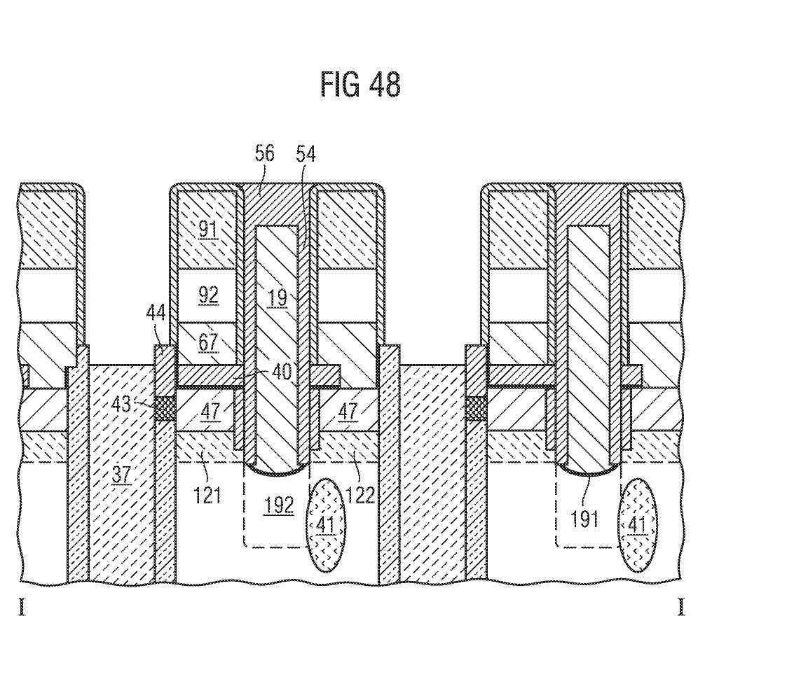

Thereafter, the material of the second capacitor electrode will be deposited. For example, titanium nitride having a thickness of approximately 35 to 50 nm will be deposited. Then, the titanium nitride material is recessed, for example, by an isotropic etching step. In particular, the material of the second capacitor electrode is recessed to a height so that the top surface of the isolation collar is disposed at a higher height than the surface of the second capacitor electrode. The resulting structure is illustrated in FIG. 48. As can be seen, the second capacitor electrode 37 extends to a height which is less than the height of the top surface of the isolation collar 32 which is disposed on the left side. On the right hand side of the trench, the conductive strap material is disposed above the substrate surface 10. The conductive strap material 43 is electrically connected with the second capacitor electrode 37. Optionally, a thin, conductive silicon dioxide layer is disposed between the conductive strap material 43 and the second capacitor electrode 37. Above the conductive strap material a further silicon dioxide portion 44 is disposed. The second capacitor electrode extends to a height above the substrate surface 10.

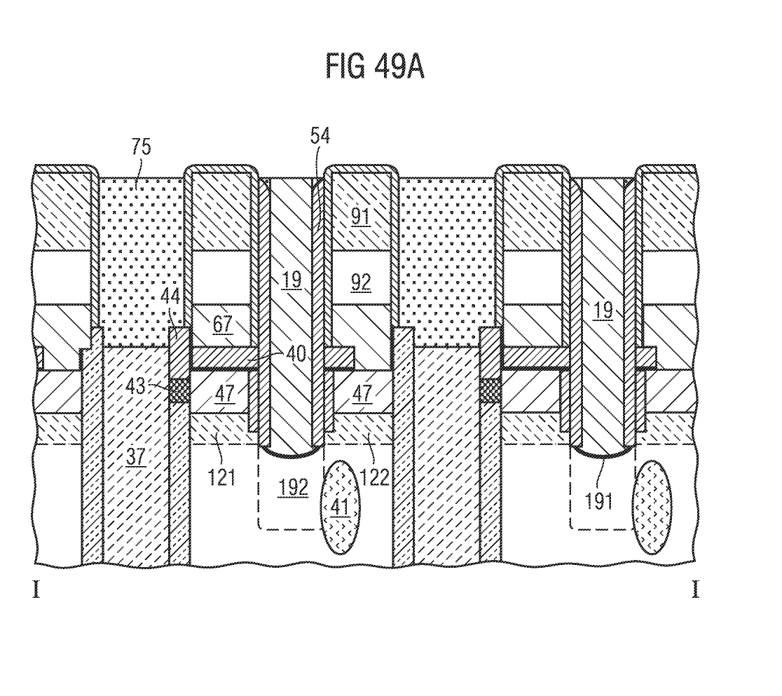

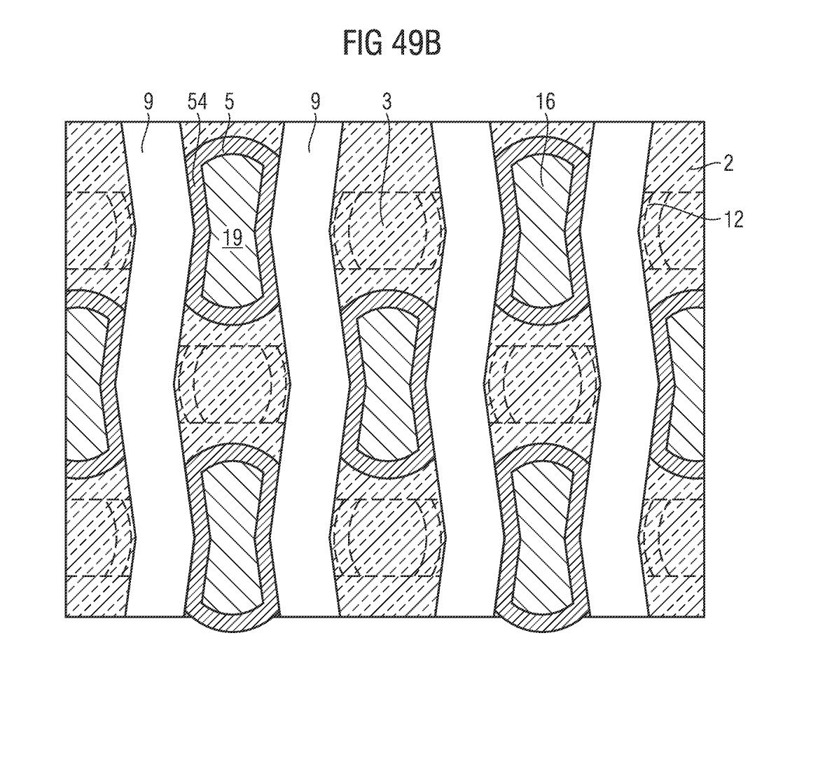

In the next process, a further insulating material will be provided. For example, a spin-on glass 75 may be deposited, followed by a CMP step. The resulting structure is illustrated in FIG. 49A. As can be seen, the second capacitor electrode 37 is insulated from the portion above by the spin-on glass 75. Moreover, the surface of the gate electrode 19 is exposed.

FIG. 49B illustrates a plan view of the resulting structure. As can be seen, bitlines 9 extend so as to be adjacent to the single gate electrodes 19. Moreover, the bitlines 9 are not running above the trench capacitors 3. Accordingly, the bitlines may for example have a wiggled shape so that they may contact the corresponding second source/drain portions while at the same time not running above the trench capacitors 3.

Thereafter, the memory cell array will be completed by providing the corresponding wordlines. In particular, the materials for constituting the wordline layer stack are deposited. Thereafter, the layer stack is patterned so as to form the single wordlines. For example, the materials of the wordlines may comprise tungsten and others which are commonly employed. By way of example, these materials may be deposited using a chemical vapour deposition (CVD) method or a physical vapour deposition (PVD) method. The resulting structure is illustrated in FIGS. 1A and C respectively. FIG. 50 illustrates a schematic plan view of the resulting structure.

FIG. 50 illustrates a layout of a memory device incorporating the memory cell array of the present invention. In the central portion of the depicted memory device, the memory cell array 106 including the memory cells 100 is disposed. The memory cells 100 are arranged in a checkerboard pattern, so that individual memory cells are diagonally arranged with respect to each other. Each memory cell includes a storage capacitor with a first capacitor electrode 31, a capacitor dielectric 38 as well as a second capacitor electrode 37, and an access transistor 16. The first source/drain region 121 of the transistor 16 is connected with the second capacitor electrode 37, and the second source/drain region 122 of the transistor is connected with a corresponding bitline 9. The wordline 8 is connected with a gate electrode 19 of the transistor 16.

In operation, one memory cell 10 is selected, for example, by activating a wordline 8. The wordline 8 is coupled to the gate electrode 19 of a corresponding one of the transistors 16. The bitline 9 is coupled to the second source/drain region 122 of one of the transistors 16. The transistor 16 is then turned on, coupling the charge stored in the capacitor 3 to the associated bitline 9. The sense amplifier 104 senses the charge coupled from the capacitor 3 to the bitline 9. The sense amplifier 104 compares the obtained signal with a reference signal obtained from a neighboring bitline 9 sensing a signal from a memory cell 100 connected with a neighboring wordline 8 that is not activated.

The sense amplifier 6 forms part of the core circuitry, in which as well the wordline drivers 103 are arranged. The peripheral portion 101 further includes the support region 105 disposed outside the core circuitry 102. A plurality of transistors are formed in the peripheral portion 101. As has been described above, for example the gate electrodes of the peripheral portion 101 may be patterned from the same layer stack which also forms the bitlines 9 of the array portion 100.

As is clearly to be understood, the specific description of the layout of the memory device is in no way limiting, and the invention may as well be implemented to any other configuration.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory cell array, comprising:
a plurality of memory cells, each memory cell including a storage capacitor and an access transistor;
a plurality of bit lines orientated in a first direction;
a plurality of word lines orientated in a second direction, the second direction being perpendicular to the first direction;
a semiconductor substrate with a surface, a plurality of active areas being formed in the semiconductor substrate, each active area extending in the second direction;
the access transistors being partially formed in the active areas and electrically coupling corresponding ones of the storage capacitors to corresponding bit lines, wherein:
a gate electrode of each of the access transistors is connected with a corresponding word line,
a capacitor dielectric of the storage capacitor has a relative dielectric constant of more than 8, and
the word lines are disposed above the bit lines.

2. The memory cell array of claim 1, wherein each gate electrode is disposed in a groove, the groove extending in the semiconductor substrate.

3. The memory cell array of claim 1, wherein each of the gate electrodes comprises plate-like portions so that the gate electrode encloses a channel of the transistor at three sides thereof.

4. The memory cell array of claim 1, wherein each storage capacitor is a trench capacitor including a first capacitor electrode, a second capacitor electrode, and the dielectric layer is disposed between the first and second capacitor electrodes, wherein the first and second capacitor electrodes and the dielectric layer are disposed in a trench extending in the semiconductor substrate.

5. The memory cell array of claim 1, wherein the gate electrode is connected with a corresponding word line via a gate contact.

6. The memory cell array of claim 1, wherein each of the access transistors comprises:
a first and a second source/drain regions as well as a channel formed between the first and second source/drain regions, the gate electrode controlling an electrical conductivity of the channel; and
an insulating spacer electrically insulating the gate electrode from the first and second source/drain regions, the spacer extending perpendicularly with respect to the substrate surface.

7. The memory cell array of claim 1, wherein a channel connecting a first and a second source/drain regions includes vertical portions and a horizontal portion with respect to the substrate surface, the horizontal portion being adjacent to a bottom side of the gate electrode.

8. The memory cell array of claim 1, wherein the word lines are made of a metal.

9. A memory cell array, comprising:
a plurality of memory cells, each memory cell including a storage capacitor and an access transistor;
a plurality of bit lines orientated in a first direction;
a plurality of word lines orientated in a second direction, the second direction being perpendicular to the first direction;
a semiconductor substrate with a surface, a plurality of active areas being formed in the semiconductor substrate, each active area extending in the second direction;
the access transistors being partially formed in the active areas and electrically coupling corresponding ones of the storage capacitors to corresponding bit lines, each transistor comprising:
a first source/drain region connected with an electrode of the storage capacitor,
a second source/drain region adjacent to the substrate surface,
a channel connecting the first and the second source/drain regions, the channel region being disposed in the active area, and
a gate electrode disposed along the channel region, the gate electrode controlling an electric current flowing between the first and the second source/drain regions, the gate electrode being connected with one of the word lines,
wherein each of the gate electrodes includes a bottom side, each word line includes a bottom side, a bottom side of the gate electrodes being disposed beneath the bottom side of the word lines, and the word lines being disposed above the bit lines, wherein each of the storage capacitor comprises a first and a second capacitor electrode, and a dielectric layer disposed between the first and the second capacitor electrodes, the capacitor dielectric having a relative dielectric constant of more than 8.

10. A memory cell array, comprising:
a plurality of memory cells, each memory cell including a storage capacitor and an access transistor;
a plurality of bit lines orientated in a first direction;
a plurality of word lines orientated in a second direction, the second direction being perpendicular to the first direction;
a semiconductor substrate with a surface, a plurality of active areas being formed in the semiconductor substrate, each active area extending in the second direction;
the access transistors being partially formed in the active areas and electrically coupling corresponding ones of the storage capacitors to corresponding bit lines, wherein an electrode of the capacitor is connected with the access transistor via a conductive structure which is disposed above the semiconductor substrate, wherein the gate electrode of each of the access transistors is connected with a corresponding word line, and wherein the word lines are disposed above the bit lines.

11. The memory cell array of claim 10, wherein each gate electrode is disposed in a groove, the groove extending in the semiconductor substrate.

12. The memory cell array of claim 10, wherein each storage capacitor is a trench capacitor including a first capacitor electrode, a second capacitor electrode, and a dielectric layer disposed between the first and second capacitor electrodes, the first and second capacitor electrodes and the dielectric layer being disposed in a trench extending in the semiconductor substrate.

13. The memory cell array of claim 10, wherein the gate electrode is connected with a corresponding word line via a gate contact.

14. The memory cell array of claim 10, wherein each of the access transistors comprises:
a first and a second source/drain region as well as a channel formed between the first and second source/drain region, the gate electrode controlling an electrical conductivity of the channel; and
an insulating spacer electrically insulating the gate electrode from the first and second source/drain regions, the insulating spacer extending perpendicularly with respect to the substrate surface.

15. The memory cell array of claim 10, wherein each of the access transistors comprises a first and a second source/drain regions, the channel connecting the first and second source/drain regions includes vertical portions and a horizontal portion with respect to the substrate surface, the horizontal portion being adjacent to the bottom side of the gate electrode.

16. The memory cell array of claim 10, wherein the word lines are made of a metal.

17. The memory cell array of claim 10, wherein each of the gate electrodes comprises plate-like portions so that the gate electrode encloses a channel of the transistor at three sides thereof.

18. The memory cell array of claims 10, wherein each gate electrode is disposed in a groove, the groove extending in the semiconductor substrate.

19. A memory cell array, comprising:
a plurality of memory cells, each memory cell including a storage capacitor and an access transistor;
a plurality of bit lines orientated in a first direction;
a plurality of word lines orientated in a second direction, the second direction being perpendicular to the first direction;
a semiconductor substrate with a surface, a plurality of active areas being formed in the semiconductor substrate, each active area extending in the second direction;
the access transistors being partially formed in the active areas and electrically coupling corresponding ones of the storage capacitors to corresponding bit lines, wherein:
the gate electrode of each of the transistors is disposed in a groove extending in the semiconductor substrate;
the gate electrode comprises plate-like portions so that the gate electrode encloses a channel of the transistor at three sides thereof;
the gate electrode of each of the access transistors is connected with a corresponding word line, and wherein the word lines are disposed above the bit lines.

20. The memory cell array of claim 19, wherein each storage capacitor is a trench capacitor including a first capacitor electrode, a second capacitor electrode, and a dielectric layer disposed between the first and second capacitor electrodes, the first and second capacitor electrodes and the dielectric layer being disposed in a trench extending in the semiconductor substrate.

21. The memory cell array of claim 19, wherein the gate electrode is connected with a corresponding word line via a gate contact.

22. The memory cell array of claim 19, wherein each of the access transistors comprises:
a first and a second source/drain region as well as a channel formed between the first and second source/drain region, the gate electrode controlling an electrical conductivity of the channel; and
an insulating spacer electrically insulating the gate electrode from the first and second source/drain regions, the insulating spacer extending perpendicularly with respect to the substrate surface.

23. The memory cell array of claim 19, wherein the channel connecting the first and second source/drain regions includes vertical portions and a horizontal portion with respect to the substrate surface, the horizontal portion being adjacent to the bottom side of the gate electrode.

24. The memory cell array of claim 19, wherein the word lines are made of a metal.

25. A method of forming a memory cell array, comprising:
providing a semiconductor substrate having a surface;
providing storage capacitors;
defining active areas in the semiconductor substrate;
providing access transistors in corresponding ones of the active areas;
providing a plurality of bit lines extending along a first direction; and
providing a plurality of word lines extending along a second direction, each word line being connected with a plurality of gate electrodes,
wherein the active areas extend in the second direction,
wherein providing bit lines occurs before providing word lines; and
wherein providing a capacitor dielectric of the storage capacitor occurs after providing the bit lines.

26. The method of claim 25, wherein providing a storage capacitor comprises:
forming a trench extending in the semiconductor substrate, the trench having a sidewall,
providing a first capacitor electrode adjacent to the sidewall, filling a trench with a sacrificial material, the sacrificial material being removed after providing the bit lines.

27. The method of claim 26, comprising:
after filling the trench with a sacrificial material part of the sacrificial material protrudes from the substrate surface thereby forming a protruding portion;
providing an access transistor comprises providing a first and a second source/drain regions, a channel connecting the first and second source/drain regions, the gate electrode being disposed along the channel;
an additional ion implantation is performed so as to implant ions into the second source/drain region, this additional ion implantation being an angled ion implantation taking the protruding portions as a shadowing mask.

28. The method of claim 25, wherein the capacitor dielectric is a dielectric having a relative dielectric constant larger than 8.

29. The method of claim 25, further comprising
providing a first and a second source/drain region;
providing an insulating spacer, the insulating spacer electrically insulating the gate electrode from the first and second source/drain regions, the insulating spacer extending perpendicularly with respect to the substrate surface.

30. The method of claim 25, wherein providing the gate electrodes occurs after providing the bit lines.

31. A method of forming a memory cell array, comprising:
providing a semiconductor substrate having a surface;
providing storage capacitors by forming trenches in the semiconductor substrate, the trenches having sidewalls, and filling the trenches with suitable materials so that part of the materials protrude from the substrate surface thereby forming protruding portions;
defining active areas in the semiconductor substrate;
providing access transistors in corresponding ones of the active areas, by providing a first and a second source/drain regions, a channel connecting the first and second source/drain regions and a gate electrode that is disposed along the channel;
providing a plurality of bit lines extending along a first direction, each of the bit lines being in contact with a corresponding second source/drain region; and
providing a plurality of word lines extending along a second direction, each word line being connected with a plurality of gate electrodes, wherein
the active areas extend in the second direction,
providing bit lines occurs before providing word lines; and
an additional ion implantation is performed so as to implant ions into the second source/drain region, this additional ion implantation being an angled ion implantation taking the protruding portions as a shadowing mask.

32. The method of claim 31, wherein the capacitor dielectric is a dielectric having a relative dielectric constant larger than 8.

33. The method of claim 31, further comprising
providing an insulating spacer, the insulating spacer electrically insulating the gate electrode from the first and second source/drain regions, the insulating spacer extending perpendicularly with respect to the substrate surface.

34. The method of claim 31, wherein providing the gate electrodes occurs after providing the bit lines.

35. A method of forming a memory cell array, comprising:
providing a semiconductor substrate having a surface;
providing storage capacitors;
defining active areas in the semiconductor substrate;
providing access transistors in corresponding ones of the active areas by providing corresponding gate electrodes disposed along a channel of the transistors, respectively;
providing a plurality of bit lines extending along a first direction; and
providing a plurality of word lines extending along a second direction, each word line being connected with a plurality of gate electrodes,
wherein the active areas extend in the second direction,
wherein providing bit lines occurs before providing word lines; and
wherein providing the gate electrodes occurs after providing the bit lines.

36. The method of claim 35, wherein providing the gate electrode comprises defining a groove extending in the semiconductor substrate.

37. The method of claim 35, wherein the capacitor dielectric is a dielectric having a relative dielectric constant larger than 8.

38. The method of claim 35, further comprising
providing a first and a second source/drain region;
providing an insulating spacer, the insulating spacer electrically insulating the gate electrode from the first and second source/drain regions, the insulating spacer extending perpendicularly with respect to the substrate surface.

39. A memory cell array, comprising:
a plurality of memory cells, each memory cell comprising a means for storing an electrical charge and an access transistor,
a plurality of bit lines orientated in a first direction;
a plurality of word lines orientated in a second direction, the second direction being perpendicular to the first direction;
the access transistors coupling corresponding ones of the means for storing an electrical charge to corresponding bit lines, wherein:
each of the access transistors comprises means for controlling an electrical current flow, the means being connected with a corresponding word line,
a capacitor dielectric of the means for storing an electrical charge has a relative dielectric constant of more than 8, and
the word lines are disposed above the bit lines.
